(19) United States
(12) Patent Application Publication
(10) Pub. No.: US 2026/0324494 A1
(43) Pub. Date: Oct. 15, 2026

(54) SEMICONDUCTOR PACKAGE INCLUDING MULTIPLE MOLDING LAYERS

(71) Applicant: SAMSUNG ELECTRONICS CO., LTD., Suwon-si (KR)

(72) Inventors: Eun Young LEE, Suwon-si (KR); Sangkyu LEE, Suwon-si (KR)

(73) Assignee: SAMSUNG ELECTRONICS CO., LTD., Suwon-si (KR)

(21) Appl. No.: 19/414,712

(22) Filed: Dec. 10, 2025

(30) Foreign Application Priority Data
Apr. 11, 2025 (KR) 10-2025-0047595

(51) Int. Cl. H10W 74/47; H10W 70/60; H10W 72/00; H10W 90/24

(52) U.S. Cl. CPC H10W 74/473; H10W 70/611; H10W 72/823; H10W 90/24

(57) ABSTRACT

A semiconductor package including an intermediate redistribution structure with a first thickness, a first package structure comprising a first molding layer that is in contact with a back side of the intermediate redistribution structure, a second package structure comprising a second molding layer that is in contact with a front side that is opposite to the back side of the intermediate redistribution structure, and a first redistribution structure that is in contact with a front side of the second molding layer and with a second thickness that is thicker than the first thickness, wherein the second molding layer has a thermal expansion coefficient that is less than a thermal expansion coefficient of the first molding layer.

### CROSS-REFERENCE TO RELATED APPLICATIONS

This application claims the benefit of Korean Patent Application No. 10-2025-0047595, filed on Apr. 11, 2025, in the Korean Intellectual Property Office, the disclosure of which is incorporated herein by reference in its entirety.

### BACKGROUND

### 1. Field

Example embodiments relate to a semiconductor package.

### 2. Description of the Related Art

With the rapid development of the electronics industry and the demands of users, electronic devices are becoming smaller and lighter. As electronic devices become smaller and lighter, the semiconductor packages used in the electronic devices are also becoming smaller and lighter, and the semiconductor packages are required to have high reliability along with high performance and large capacity. As the semiconductor packages show higher performance and higher capacitance, their power consumption is increasing. Accordingly, the importance of the structure of the semiconductor package is increasing in order to respond to the size/performance of the semiconductor package and to provide stable power supply to the semiconductor package.

### SUMMARY

An aspect provides a semiconductor package by which minimization of warpage and optimization of operational performance can be implemented.

The technical tasks to be achieved by the present example embodiments are not limited to the technical tasks described above, and other technical tasks may be inferred from the following example embodiments by those skilled in the art.

According to an aspect, there is provided a semiconductor package including an intermediate redistribution structure with a first thickness, a first package structure comprising a first molding layer that is in contact with a back side of the intermediate redistribution structure, a second package structure comprising a second molding layer that is in contact with a front side that is opposite to the back side of the intermediate redistribution structure and a first redistribution structure that is in contact with a front side of the second molding layer and with a second thickness that is thicker than the first thickness. A thermal expansion coefficient of the second molding layer is less than a thermal expansion coefficient of the first molding layer.

According to another aspect, there is provided a semiconductor package including an intermediate redistribution structure with a first thickness, a first semiconductor die stack comprising a plurality of first semiconductor dies that are stacked in a first step structure in a first direction intersecting a back side of the intermediate redistribution structure in the intermediate redistribution structure, a second semiconductor die stack comprising a plurality of second semiconductor dies that are stacked in a second step structure in the first direction under the intermediate redistribution structure, a first redistribution structure that is disposed on the second semiconductor die stack and with a second thickness that is thicker than the first thickness, a first molding layer covering the first semiconductor die stack and comprising a plurality of first fillers with a first average diameter, and a second molding layer covering the second semiconductor die stack and comprising a plurality of second fillers with a second average diameter that is greater than the first average diameter.

According to another aspect, there is provided a semiconductor package including an intermediate redistribution structure comprising a first number of intermediate redistribution insulation layer, a first semiconductor die stack comprising a plurality of first semiconductor dies that are stacked in a step structure in a first direction intersecting a back side of the intermediate redistribution structure in the intermediate redistribution structure, a second semiconductor die stack comprising a plurality of second semiconductor dies that are stacked in a reversal step structure in the first direction under the first semiconductor die stack, a first redistribution structure comprising a second number of first redistribution insulation layers that are stacked in the first direction, that are disposed under the second semiconductor die stack and wherein the second number is greater than the first number, a first molding layer covering the first semiconductor die stack and comprising a plurality of first fillers with a first average diameter and a first molding material configured to bury the plurality of first fillers, and a second molding layer covering the second semiconductor die stack and comprising a plurality of second fillers with a second average diameter and a second molding material configured to bury the plurality of second fillers. The first average diameter is less than the second average diameter, and a thermal expansion coefficient of the first molding material is greater than a thermal expansion coefficient of the second molding material.

According to another aspect, there is provided a method of manufacturing a semiconductor package, the method including stacking a plurality of first semiconductor dies with first conductive posts attached on a carrier substrate in a stepwise manner in a first direction intersecting a main surface of the carrier substrate, forming a first molding layer covering the plurality of first semiconductor dies on the carrier substrate, forming an intermediate redistribution structure connected with the first conductive post on the first molding layer, stacking a plurality of second semiconductor dies with second conductive posts attached on the intermediate redistribution structure in a stepwise manner in the first direction, forming a second molding layer covering the plurality of second semiconductor dies on the intermediate redistribution structure, and forming a redistribution structure connected with the second conductive posts on the second molding layer. The redistribution structure has a thickness that is thicker than a thickness of the intermediate redistribution structure, and the second molding layer has a thermal expansion coefficient that is less than a thermal expansion coefficient of the first molding layer.

According to an example embodiment, provided is the method of manufacturing a semiconductor package, wherein the first molding layer may include a first molding material and a plurality of first fillers that are buried in the first molding material, the second molding layer may include a second molding material and a plurality of second fillers that are buried in the second molding material, and a thermal expansion coefficient of the plurality of first fillers may be less than a thermal expansion coefficient of the first molding material, and a thermal expansion coefficient of the plurality of second fillers may be less than a thermal expansion coefficient of the second molding material.

According to an example embodiment, provided is the method of manufacturing a semiconductor package, wherein a content of the plurality of first fillers may be less than a content of the plurality of second fillers.

According to an example embodiment, provided is the method of manufacturing a semiconductor package, wherein the stacking the plurality of first semiconductor dies in the stepwise manner may include that the plurality of first semiconductor dies are stacked to be offset in a second direction intersecting the first direction.

According to an example embodiment, provided is the method of manufacturing a semiconductor package, wherein the stacking the plurality of second semiconductor dies in the stepwise manner may include that the plurality of second semiconductor dies are stacked to be offset in a reverse second direction that is a direction opposite to the second direction.

According to an example embodiment, provided is the method of manufacturing a semiconductor package, and the method may further include forming a through post that is connected with the intermediate redistribution structure and overlaps the first conductive post in the first direction, between forming the intermediate redistribution structure on the first molding layer and stacking the plurality of second semiconductor dies in the first direction in the stepwise manner.

According to an example embodiment, provided is the method of manufacturing a semiconductor package, wherein the forming the intermediate redistribution structure on the first molding layer may include that the intermediate redistribution structure is in direct contact with the first molding layer.

According to an example embodiment, provided is the method of manufacturing a semiconductor package, wherein the forming the redistribution structure on the second molding layer may include that the redistribution structure is direct contact with the second molding layer.

### BRIEF DESCRIPTION OF THE FIGURES

These and/or other aspects, features, and advantages of the inventive concept will become apparent and more readily appreciated from the following description of example embodiments, taken in conjunction with the accompanying drawings of which:

FIG. 1 is a schematic plan view illustrating a semiconductor package according to an example embodiment;

FIG. 2 is a drawing illustrating a cross-section taken along line A-A′ of FIG. 1;

FIG. 3 is a drawing illustrating a semiconductor package according to an example embodiment, and illustrating a cross-section taken along line A-A′ of FIG. 1;

FIG. 4 is a drawing illustrating a semiconductor package according to an example embodiment, and illustrating a cross-section taken along line A-A′ of FIG. 1;

FIG. 5 is a drawing illustrating a semiconductor package according to an example embodiment, and illustrating a cross-section taken along line A-A′ of FIG. 1;

FIG. 6 is a drawing illustrating a semiconductor package according to an example embodiment, and illustrating a cross-section taken along line A-A′ of FIG. 1;

FIG. 7 is a drawing illustrating a semiconductor package according to an example embodiment, and illustrating a cross-section taken along line A-A′ of FIG. 1;

FIG. 8 is a schematic plan view illustrating a semiconductor package according to another example embodiment;

FIG. 9 is a drawing illustrating a cross-section taken along line B-B′ of FIG. 8;

FIG. 10 is a schematic cross-sectional diagram illustrating a semiconductor package according to another example embodiment;

FIG. 11 is a schematic cross-sectional diagram illustrating a semiconductor package according to another example embodiment;

FIG. 12 is a schematic cross-sectional diagram illustrating a semiconductor package according to another example embodiment;

FIG. 13 is a schematic cross-sectional diagram illustrating a semiconductor package according to another example embodiment;

FIGS. 14A, 14B, 14C, 14D, 14E, 14F, 14G, 14H, 14I, 14J, 14K, 14L, 14M, and 14N are drawings illustrating a process sequence to explain a method of manufacturing a semiconductor package according to an example embodiment;

FIGS. 15A, 15B, 15C, and 15D are drawings illustrating a portion of a process in sequence to explain a method of manufacturing a semiconductor package according to another example embodiment; and

FIGS. 16A, 16B, 16C, and 16D are drawings illustrating a portion of a process in sequence to explain a method of manufacturing a semiconductor package according to another example embodiment.

### DETAILED DESCRIPTION

Hereinafter, example embodiments will be described in detail with reference to the attached drawings. Identical reference numerals are used for identical elements on a drawing, and repetitive descriptions for the elements are omitted.

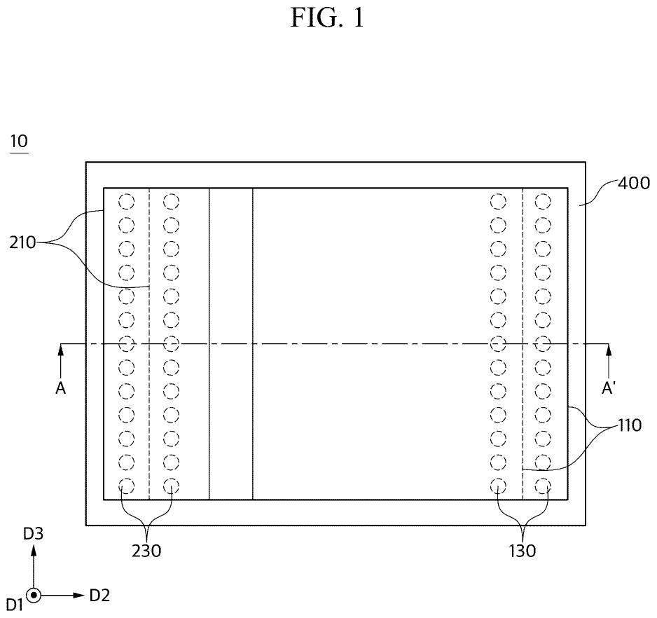

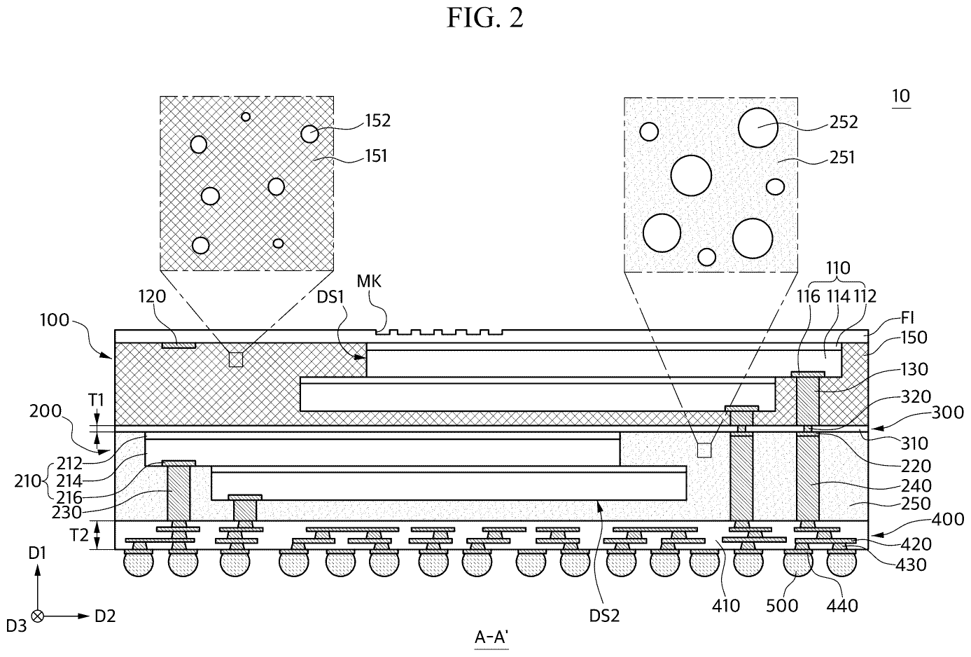

FIG. 1 is a schematic plan view illustrating a semiconductor package according to an example embodiment, and FIG. 2 is a drawing illustrating a cross-section taken along line A-A′ of FIG. 1.

According to an example embodiment, a semiconductor package 10 may include a first package structure 100, a second package structure 200, an intermediate redistribution structure 300, a redistribution structure 400, a film FI and an external terminal 500.

According to an example embodiment, the first package structure 100 may be placed above the intermediate redistribution structure 300 along the first direction D1. In the example embodiment, the first direction D1 may refer to the direction intersecting the back side, which is one of the widest areas of the intermediate redistribution structure 300. As the direction intersecting with the first direction D1, the second direction D2 may be defined as the direction in which a plurality of first semiconductor dies 110 are offset from each other. The third direction D3 may be defined as the direction intersecting the first direction D1 and the second direction D2.

In an example embodiment, the front side may indicate a surface intersecting the direction in which the second package structure 200 faces from the first package structure 100 from the perspective of the semiconductor package 10 illustrated in FIG. 2. In other words, the front side may indicate the surface intersecting the reverse direction −D1 of the first direction. The back side may indicate the side opposite to the front side. In other words, the back side may indicate the surface intersecting the first direction D1.

According to an example embodiment, the first package structure 100 may include a first semiconductor die stack DS1 comprising the plurality of first semiconductor dies 110, an alignment pad 120, a first conductive post 130 and a first molding layer 150. In the example embodiment, even though it is illustrated that the first package structure 100 includes the plurality of first semiconductor dies 110 stacked in a stepwise manner, according to an example embodiment, the first package structure 100 may include a single semiconductor die.

According to an example embodiment, the plurality of first semiconductor dies 110 constituting the first semiconductor die stack DS1 may be stacked in a step structure in the first direction D1. The plurality of first semiconductor dies 110 stacked in the step structure may be arranged offset from each other in the second direction D2. For example, among the plurality of first semiconductor dies 110, the first semiconductor die 110 positioned at the top may be misaligned in the second direction D2 with respect to the first semiconductor die 110 positioned at the bottom.

According to an example embodiment, the first semiconductor die 110 may include a first adhesive layer 112, a first chip body 114, and a first connection pad 116. The first adhesive layer 112 may extend along the back side of the first chip body 114, and a side of the first adhesive layer 112 may be aligned with a side of the first chip body 114. The first adhesive layer 112 may be attached to the back side of the first chip body 114 to allow the first semiconductor die 110 to be attached to another first semiconductor die 110 or the film FI and so on. For example, the first adhesive layer 112 of the first semiconductor die 110 located at the bottom among the first semiconductor dies 110 stacked in a stepwise manner may be attached to the front side of the first chip body 114 of another first semiconductor die 110 positioned adjacent to the first direction D1. A portion of the first adhesive layer 112 of the first semiconductor die 110 located at the bottom may contact the first molding layer 150 surrounding the first semiconductor die stack DS1.

According to an example embodiment, in the first package structure 100, the first semiconductor die 110 may be arranged such that the active surface of the first chip body 114 faces the lower side and the inactive surface faces the upper side. Unless otherwise stated in the present disclosure, the back side of the first semiconductor die 110 refers to the side that the inactive surface of the first chip body 114 faces, and the front side of the first semiconductor die 110 refers to the side that the active surface of the first chip body 114 faces. The back side of the first semiconductor die 110, which is covered by the first adhesive layer 112 being extended, may be an inactive surface.

According to an example embodiment, a semiconductor device may be formed on the active surface of the first chip body 114. The semiconductor device may include various types of individual devices. The individual devices may include a variety of microelectronic devices. For example, included may be metal-oxide-semiconductor field effect transistors (MOSFET), such as complementary metal-insulator-semiconductor (CMOS) transistors, system large scale integration (LSI) circuits, image sensors such as CMOS imaging sensors (CIS) and so on, micro-electro-mechanical systems (MEMS), active devices, and/or passive devices. In an example embodiment, the first semiconductor die 110 may be a memory semiconductor chip.

According to an example embodiment, the first adhesive layer 112 may include a non-conductive film (NCF), a non-conductive paste (NCP), an insulating polymer or an epoxy resin. However, materials included in the first adhesive layer 112 are not limited to the materials listed above.

According to an example embodiment, the first chip body 114 may include a semiconductor material such as silicon, germanium and silicon-germanium, or a group III-V compound semiconductor such as gallium phosphide (GaP), gallium arsenide (GaAs) and gallium antimonide (GaSb). According to some example embodiments, the first chip body 114 may be a silicon-on-insulator (SOI) substrate or a germanium-on-insulator (GOI) substrate.

According to an example embodiment, the first connection pad 116 may be placed on one side of the front side of the first chip body 114. The first connection pad 116 may be exposed on the front side of the first chip body 114. The first connection pad 116 may provide a terminal for electrically connecting the first semiconductor die 110 to the intermediate redistribution structure 300.

According to an example embodiment, the alignment pad 120 may be attached to the front side of the film FI. As will be explained in detail later, the alignment pad 120 may be a pad that serves as a reference for accurately attaching the first semiconductor die 110 to the target position in the process of attaching the first semiconductor die 110 to the film FI.

According to an example embodiment, the first connection pad 116 and the alignment pad 120 may include at least one metal selected from tungsten (W), aluminum (Al) and copper (Cu).

According to an example embodiment, the first conductive post 130 is connected to the first connection pad 116 and may be extended in the first direction D1. The side wall of the first conductive post 130 may be wrapped by the first molding layer 150. The first conductive post 130 is connected to the first connection pad 116 and a first intermediate redistribution via 320, thereby electrically connecting the first semiconductor die 110 and the intermediate redistribution structure 300. In the present disclosure, the expressing “being connected” may imply direct physical contact. The expressing “being electrically connected” may imply that elements are electrically connected to each other through a conductor or the like, even though the elements are not physically in direct contact with each other.

According to an example embodiment, the first conductive post 130 may have a post shape of a cylinder penetrating the first molding layer 150. However, the shape of the first conductive post 130 is not limited thereto.

According to an example embodiment, the plurality of first conductive posts 130 may be provided, and each first conductive post 130 may be connected to the corresponding first connection pad 116. The length of the first conductive post 130 in the first direction D1 may be the distance from the first connection pad 116 to which the first conductive post 130 is connected to the intermediate redistribution structure 300. Different may be the length of the first conductive post that is connected to the first semiconductor die 110 that is arranged at the top and the length of the first conductive post 130 that is connected to the first semiconductor die 110 at the bottom among the plurality of first semiconductor dies 110, in the first direction D1.

According to an example embodiment, the width of the first conductive post 130 in the horizontal direction (the first direction D1 and/or the second direction D2) may be greater than the width of the first intermediate redistribution via 320 in the horizontal direction (the first direction D1 and/or the second direction D2).

According to an example embodiment, the first conductive post 130 may include a pillar-shaped conductive plug penetrating at least a portion of the first molding layer 150 and a cylindrical conductive barrier film surrounding a side wall of the conductive plug. The conductive plug may include at least one material selected from Cu alloys such as Cu, CuSn, CuMg, CuNi, CuZn, CuPd, CuAu, CuRe and CuW, W, W alloy, Ni, Ru, and Co. The conductive barrier film may include at least one material selected from Ti, TiN, Ta, TaN, Ru, Co, Mn, WN, Ni and NiB.

According to an example embodiment, the first molding layer 150 may seal the first semiconductor die stack DS1 and the first conductive post 130 between the intermediate redistribution structure 300 and the film FI. Here, the side wall of the first molding layer 150 may be aligned with the side wall of the intermediate redistribution structure 300 and the side wall of the film FI. The first molding layer 150 may be interposed between the first semiconductor die 110 located at the lowermost layer among the plurality of first semiconductor dies 110 and the intermediate redistribution structure 300. Therefore, the plurality of first semiconductor dies 110 may be spaced apart from each other in the first direction D1 without contacting the intermediate redistribution structure 300. A more detailed explanation of the first molding layer 150 will follow later.

According to an example embodiment, the second package structure 200 may be placed below the intermediate redistribution structure 300 in the first direction D1.

According to an example embodiment, the second package structure 200 may include a second semiconductor die stack DS2 comprising a plurality of second semiconductor dies 210, a first connection pad 220, a second conductive post 230, a second through post 240, and a second molding layer 250. Hereinafter, in the description of the second package structure 200, any content that overlaps with the description of the first package structure 100 will be omitted or simplified. In the example embodiment, the term “second” in defining the second through post 240 refers to the element included in the second package structure 200. In the example embodiment, even though it is illustrated that the second package structure 200 includes the plurality of second semiconductor dies 210 stacked in a stepwise manner, according to an example embodiment, the second package structure 200 may include a single semiconductor die.

According to an example embodiment, as with the first semiconductor die stack DS1, the plurality of second semiconductor dies 210 constituting the second semiconductor die stack DS2 may be stacked in a step structure in the first direction D1. However, according to an example embodiment, the plurality of second semiconductor dies 210 may be offset in a direction opposite to the direction in which the plurality of first semiconductor dies 110 are offset (for example, the reverse direction −D2 of the second direction). For example, among the plurality of second semiconductor dies 210, the second semiconductor die 210 positioned on the upper side may be misaligned in the reverse direction −D2 of the second direction with respect to the second semiconductor die 210 positioned on the lower side. In the present disclosure, the structure that is stacked in a step-like manner along the first direction (D1 direction) while being offset in the reverse direction −D2 of the second direction may be defined as a reverse step structure.

According to an example embodiment, the second semiconductor die 210 may include a second adhesive layer 212, a second chip body 214, and a second connection pad 216. The second adhesive layer 212 may extend along the back side of the second chip body 214, and be aligned with a side of the second chip body 214. The second adhesive layer 212 may be attached to the back side of the second chip body 214 to allow the second semiconductor die 210 to be attached to another second semiconductor die 210 or the intermediate redistribution structure 300. A portion of the second adhesive layer 212 of the second semiconductor die 210 located at the bottom may contact the second molding layer 250. The relationship between the second adhesive layer 212 and the second chip body 214 may be similar to the relationship between the first adhesive layer 112 and the first chip body 114.

According to an example embodiment, as with the first semiconductor die 110, the second semiconductor die 210 may be placed in order for the active surface of the second chip body 214 to face the lower side and the inactive surface to face the upper side within the second package structure 200. As with the first chip body 114, a semiconductor device may be formed on the active surface of the second chip body 214. Since the semiconductor device is described in detail above, description on the semiconductor device is omitted below. In an example embodiment, the second semiconductor die 210 may be a memory semiconductor chip.

According to an example embodiment, the material included in the second adhesive layer 212 may be substantially identical to the material included in the first adhesive layer 112. The material included in the second chip body 214 may be substantially identical to the material included in the first chip body 114. Therefore, any repetitive explanations will be omitted below.

According to an example embodiment, the second connection pad 216 may be located on a portion of the front side of the second chip body 214. The second connection pad 216 may be exposed on the front side of the second chip body 214. The second connection pad 216 may provide a terminal for electrically connecting the second semiconductor die 210 to the redistribution structure 400.

According to an example embodiment, the material included in the second connection pad 216 may be substantially identical to the material included in the first connection pad 116. Therefore, any repetitive explanations will be omitted below.

According to an example embodiment, the second conductive post 230 may be connected to the second connection pad 216 and extended in the first direction D1. The side wall of the second conductive post 230 may be covered by the second molding layer 250. The second conductive post 230 is connected to the second connection pad 216 and a redistribution via 430, thereby electrically connecting the second semiconductor die 210 and the redistribution structure 400. According to an example embodiment, a pad may be formed on the back side of the redistribution structure 400 to which the second conductive post 230 is bonded.

According to an example embodiment, the shape of the second conductive post 230 is substantially identical to the shape of the first conductive post 130, and thus a detailed description on the shape of the second conductive post 230 will be omitted.

According to an example embodiment, the plurality of second conductive posts 230 may be provided, and each of the plurality of second conductive posts 230 may be connected to the corresponding second connection pad 216. The length of the second conductive post 230 in the first direction D1 may be the distance from the second connection pad 216 to which the second conductive post 230 is connected to the redistribution structure 400. Different may be the length of the second conductive post 230 connected to the second semiconductor die 210 located at the top and the length of the second conductive post 230 connected to the second semiconductor die 210 located at the bottom among the plurality of second semiconductor dies 210, in the first direction D1.

According to an example embodiment, the material included in the second conductive post 230 may be substantially identical to the material included in the first conductive post 130. Therefore, any repetitive explanations will be omitted below.

According to an example embodiment, the first connection pad 220 may be placed on the front side of the intermediate redistribution structure 300. The first connection pad 220 may be connected to the first intermediate redistribution via 320 of the intermediate redistribution structure 300, providing a terminal for the second through post 240 to be connected to the intermediate redistribution structure 300.

According to an example embodiment, the second through post 240 may provide an electrical connection path for the first semiconductor die stack DS1 to be electrically connected to the redistribution structure 400. The second through post 240 may pass through the second molding layer 250 and be connected to the first connection pad 220 and the redistribution via 430. According to an example embodiment, a pad to which the second through post 240 will be bonded may be formed on the back side of the redistribution structure 400.

According to an example embodiment, the length of the second through post 240 in the first direction D1 may be longer than the length of the second conductive post 230 in the first direction D1.

According to an example embodiment, the material included in the second through post 240 may be substantially identical to the material included in the first conductive post 130. Therefore, any repetitive explanations will be omitted below.

According to an example embodiment, the intermediate redistribution structure 300 may be placed between the first package structure 100 and the second package structure 200. The intermediate redistribution structure 300 may include an intermediate redistribution insulation layer 310 and the first intermediate redistribution via 320.

According to an example embodiment, the front side of the intermediate redistribution insulation layer 310 may be in contact with the second molding layer 250 and the second semiconductor die stack DS2, and the back side of the intermediate redistribution insulation layer 310 may be in contact with the first molding layer 150. Even though FIG. 2 illustrates that the intermediate redistribution insulation layer 310 is a single-layer, according to an example embodiment, the intermediate redistribution insulation layer 310 may have a structure in which multiple insulation layers are laminated at different levels in the first direction D1.

According to an example embodiment, the first intermediate redistribution via 320 may be extended in the first direction D1 within the intermediate redistribution insulation layer 310. The first intermediate redistribution via 320 may be connected to the first connection pad 220 and the first conductive post 130 through the intermediate redistribution insulation layer 310. Even though it is not illustrated in detail in the example embodiment, according to an example embodiment, the first intermediate redistribution via 320 may have a tapered shape with a width that varies along the first direction D1.

According to an example embodiment, the intermediate redistribution insulation layer 310 may include silicon oxide, silicon nitride, silicon oxynitride, an insulating material having a lower dielectric constant than silicon oxide, or a combination thereof. Further, the first intermediate redistribution via 320 may include at least one metal selected from tungsten (W), aluminum (Al) and copper (Cu).

According to an example embodiment, the redistribution structure 400 may be placed underneath the second package structure 200 in the first direction D1. The redistribution structure 400 may include a redistribution insulation layer 410, a redistribution pattern 420, the redistribution via 430, and a redistribution pad 440.

According to an example embodiment, the redistribution insulation layer 410 may be placed on the front side of the second molding layer 250. The redistribution insulation layer 410 may have a structure in which multiple insulation layers are laminated at different levels in the first direction D1.

According to an example embodiment, the redistribution via 430 may be connected to the second through post 240 or the second conductive post 230. The plurality of redistribution vias 430 may be provided within the redistribution insulation layer 410. The plurality of redistribution vias 430 may be arranged within the redistribution insulation layer 410 at different levels along the first direction D1. Among the plurality of redistribution vias 430 at different levels in the first direction D1, the redistribution vias 430 located closest to the second package structure 200 may be connected to the second through post 240 or the second conductive post 230. However, according to an example embodiment, a conductive pad may be provided between the redistribution via 430 and the second through post 240 or between the redistribution via 430 and the second conductive post 230.

According to an example embodiment, when the redistribution insulation layer 410 has a structure in which multiple insulation layers are laminated at different levels in the first direction D1, a back side of a top redistribution insulation layer 510 may be arranged so that the back side of the redistribution via 430 is exposed. However, according to an example embodiment, when a conductive pad is provided between the redistribution via 430 and the second through post 240 or between the redistribution via 430 and the second conductive post 230, a back side of the above conductive pad may be exposed to the back side of the top redistribution insulation layer 410.

According to an example embodiment, the redistribution pattern 420 may extend in a horizontal direction (the first direction D1 and/or the second direction D2) within the redistribution insulation layer 410. The redistribution pattern 420 may provide electrical wiring in a horizontal direction (the first direction D1 and/or the second direction D2) within the redistribution insulation layer 410. The plurality of redistribution patterns 420 may be provided as multi-layered patterns with different levels in the first direction D1.

According to an example embodiment, the front side of the redistribution pad 440 may be positioned so as to be exposed on the front side of the redistribution insulation layer 410. According to an example embodiment, when the redistribution insulation layer 410 has a structure in which multiple insulation layers are laminated at different levels in the first direction D1, the front side of the redistribution pad 440 may be exposed on the front side of the bottom redistribution insulation layer 410. The redistribution pad 440 may be physically connected to the external terminal 500. According to an example embodiment, at least a portion of a side of the redistribution pad 440 may be exposed.

According to an example embodiment, the redistribution via 430 may be placed between the redistribution pad 440 and the redistribution pattern 420, or between a pair of redistribution patterns 420 at different levels in the first direction D1. The redistribution via 430 may be in contact with the back side of the redistribution pad 440 and the front side of the redistribution pattern 420, allowing a physical connection between the redistribution pad 440 and the redistribution pattern 420. Alternatively, the redistribution via 430 is in contact with the front side of the second conductive post 230 and the back side of the redistribution pattern 420, thereby allowing a physical connection between the second conductive post 230 and the redistribution pattern 420. Alternatively, the redistribution via 430 is in contact with the front side of the second through post 240 and the back side of the redistribution pattern 420, thereby allowing a physical connection between the second through post 240 and the redistribution pattern 420. Alternatively, the redistribution via 430 may physically connect between the redistribution patterns 420 in a multi-layer structure.

According to an example embodiment, the redistribution via 430 may have a tapered shape that as the redistribution via 430 along the first direction D1 gets closer to the second package structure 200, the width of the redistribution via 430 becomes narrower.

According to an example embodiment, the redistribution insulation layer 410 may include silicon oxide, silicon nitride, silicon oxynitride, an insulating material having a lower dielectric constant than silicon oxide, or a combination thereof. The redistribution pattern 420, the redistribution via 430, and the redistribution pad 440 may include at least one metal selected from tungsten (W), aluminum (Al) and copper (Cu).

According to an example embodiment, a plurality of external terminals 500 may be provided, and each of the plurality of external terminals 500 may be attached to the redistribution pad 440. When the semiconductor package 10 according to the example embodiment is mounted on another semiconductor device, the external terminal 500 may provide a terminal for connection to other semiconductor devices. For example, the “other semiconductor devices” may be an interposer, a printed circuit board (PCB), or another semiconductor package. The external terminal 500 may be, for example, a solder ball or a bump.

According to an example embodiment, the film FI may be placed on the first package structure 100. The film FI may extend along the back side of the first molding layer. The film FI may extend along the back side of the first adhesive layer 112 of the first semiconductor die 110 positioned at the uppermost end of the plurality of first semiconductor dies 110. A marking pattern MK indicating identification information of the semiconductor package 10 may be formed on the top part of the film FI. The identification information referred to here may include various information having traceability of the semiconductor package 10, such as process number, a manufacturing company, a manufacturing date, a product name, a product type, and so on. The marking pattern MK may include symbols, numbers, letters, as well as a two-dimensional barcode, which is a more indirect means of identification. For example, 2D barcodes may be implemented in various types, such as data matrix and QR code.

According to an example embodiment, the film FI may include an NCF, an NCP, an insulating polymer or an epoxy resin.

In another example embodiment, the semiconductor package 10 may not include the film FI and the marking pattern MK may be formed on the back side of the first molding layer 150 where the back side is exposed.

According to an example embodiment, the first molding layer 150 surrounds the first semiconductor die stack DS1 and may be in contact with the intermediate redistribution structure 300. The second molding layer 250 surrounds the second semiconductor die stack DS2 and may be in contact with the intermediate redistribution structure 300 and the redistribution structure 400. The area in contact between the first molding layer 150 and the intermediate redistribution structure 300 may be greater than the area in contact between the second molding layer 250 and the intermediate redistribution structure 300. The second semiconductor die stack DS2 may be in direct contact with the intermediate redistribution structure 300. The first semiconductor die stack DS1 may not be in direct contact with the intermediate redistribution structure 300, and the first molding layer 150 may be interposed between the first semiconductor die stack DS1 and the intermediate redistribution structure 300. Since both the second molding layer 250 and the second semiconductor die stack DS2 are in contact with the front side of the intermediate redistribution structure 300, relatively, the area where the second molding layer 250 comes into contact with the intermediate redistribution structure 300 is narrower than the area where the first molding layer 150 comes into contact with the intermediate redistribution structure 300.

According to an example embodiment, the second molding layer 250 is in contact with the redistribution structure 400, but the first molding layer 150 is not in contact with the redistribution structure 400. The first molding layer 150 may be spaced apart from the redistribution structure 400, with the intermediate redistribution structure 300 and the second molding layer 250 interposed therebetween.

According to an example embodiment, the second thickness T2 of the redistribution structure 400 in the first direction D1 may be thicker than the first thickness T1 of the intermediate redistribution structure 300 in the first direction D1. The second thickness T2 of the redistribution structure 400 being thicker than the first thickness T1 of the intermediate redistribution structure 300 indicates that the content of the redistribution insulation layer 410 is greater than the content of the intermediate redistribution insulation layer 310. Here, the term “content” may refer to an amount in volume or a number of molecules, and “greater content” may refer to “more amount in volume” or “a greater number of molecules”.

According to an example embodiment, the thermal expansion coefficient of the redistribution insulation layer 410 and the intermediate redistribution insulation layer 310 may be greater than the thermal expansion coefficient of the first molding layer 150 and the second molding layer 250. As the thickness of the redistribution structure 400 or the intermediate redistribution structure 300 increases, the degree of expansion due to thermal energy may increase. When the second thickness T2 of the redistribution structure 400 is thicker than the first thickness T1 of the intermediate redistribution structure 300, the degree of thermal expansion of the redistribution structure 400 is greater than the degree of thermal expansion of the intermediate redistribution structure 300. When the semiconductor package 10 is subjected to unbalanced thermal stress, the smiling warpage phenomenon may occur in which the bottom part of the semiconductor package 10 expands in the horizontal direction (the first direction D1 and/or the second direction D2). Conversely, in a room temperature or low temperature environment, a crying warpage phenomenon may occur in which the bottom part of the semiconductor package 10 is relatively shrunk in the horizontal direction (the first direction D1 and/or the second direction D2) due to unbalanced thermal stress.

According to an example embodiment, the thermal expansion coefficient of the second molding layer 250 may be lower than the thermal expansion coefficient of the first molding layer 150. The thermal expansion coefficient of the second molding layer 250 being lower than the thermal expansion coefficient of the first molding layer 150 indicates that when heat energy is applied, the degree of volume expansion of the second molding layer 250 is lower than the degree of volume expansion of the first molding layer 150. The thermal expansion coefficient of the second molding layer 250, located close to the redistribution structure 400, which is thick and has a relatively large degree of thermal expansion, may be lower than the thermal expansion coefficient of the first molding layer 150, which is located close to the thin intermediate redistribution structure 300. Since the second molding layer 250 is in direct contact with the intermediate redistribution structure 300 and the first molding layer 150 is in direct contact with the redistribution structure 400, the strain due to tensile stress of the heated intermediate redistribution structure 300 and the redistribution structure 400 may be reduced by the first molding layer 150 and the second molding layer 250.

According to an example embodiment, the first molding layer 150 may include a first molding material 151 and a plurality of first fillers 152. The first molding material 151 may be an insulating material forming the basis of the first molding layer 150. The plurality of first fillers 152 may be inorganic particles embedded and dispersed within the first molding material 151. Similarly, the second molding layer 250 may include a second molding material 251 and a plurality of second fillers 252. The second molding material 251 may be an insulating material forming the basis of the second molding layer 250, and the plurality of second fillers 252 may be inorganic particles embedded and dispersed within the second molding material 251.

According to an example embodiment, the first molding material 151 and the second molding material 251 may be composed of different materials. The thermal expansion coefficient of the first molding material 151 may be greater than the thermal expansion coefficient of the second molding material 251. For example, the first molding material 151 and the second molding material 251 may include a thermosetting resin such as an epoxy resin. However, materials of the first molding material 151 and the second molding material 251 are not limited to epoxy resin.

According to an example embodiment, the plurality of first fillers 152 may be of different sizes. Likewise, the plurality of second fillers 252 may also be of different sizes. Here, the average diameter of the plurality of first fillers 152, which are of different sizes, may be less than the average diameter of the plurality of second fillers 252. The thermal expansion coefficient of the plurality of first fillers 152 and the plurality of second fillers 252 may be lower than the thermal expansion coefficient of the first molding material 151 and the thermal expansion coefficient of the second molding material 251. In the example embodiment, the average diameter of the plurality of first fillers 152 being less than the average diameter of the plurality of second fillers 252 indicates that the content of plurality of first fillers 152 is less than the content of plurality of second fillers 252. According to an example embodiment, even though the number of the plurality of first fillers 152 is greater than the number of the plurality of second fillers 252, the total content of plurality of first fillers 152 is less than the total content of plurality of second fillers 252.

According to an example embodiment, since the thermal expansion coefficient of the filler is lower than the thermal expansion coefficient of the molding material, the higher the filler content in the molding material, the lower the thermal expansion coefficient of the molding layer. For example, the thermal expansion coefficient of the first molding layer 150 may be 20 ppm/K or, and the thermal expansion coefficient of the second molding layer 250 may be 10 ppm/K or less. The diameter of the largest first filler 152 among the plurality of first fillers 152 may be 10μm or greater, and the diameter of the second filler 252 having the largest diameter among the plurality of second fillers 252 may be 10 μm or less.

According to an example embodiment, the plurality of first fillers 152 and the plurality of second fillers 252 may include silica or a silica compound. However, the substances included in the plurality of first fillers 152 and the plurality of second fillers 252 are not limited to silica.

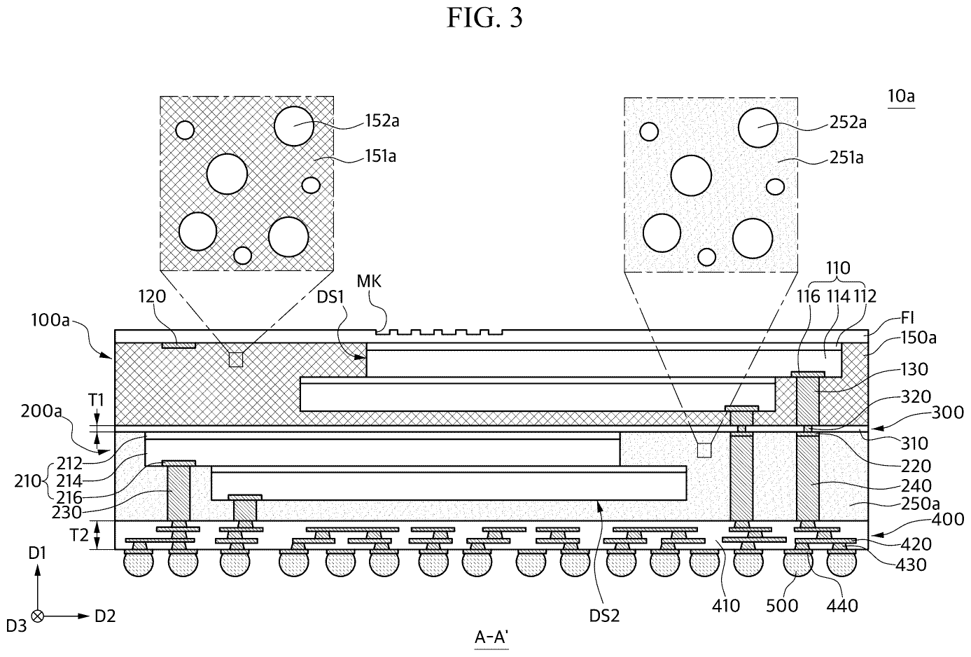

FIG. 3 is a drawing illustrating a semiconductor package according to an example embodiment, and illustrating a cross-section taken along line A-A′ of FIG. 1.

A semiconductor package 10a illustrated in FIG. 3 is almost identical or similar to the semiconductor package 10 illustrated in FIG. 1 and FIG. 2, except for the difference between a first molding layer 150a and a second molding layer 250a. Repetitive description on the elements mentioned with reference to FIG. 1 and FIG. 2 will be omitted or simplified below.

According to an example embodiment, a first package structure 100a of the semiconductor package 10a may include the first molding layer 150a surrounding the first semiconductor die stack DS1. A second package structure 200a of the semiconductor package 10a may include the second molding layer 250a surrounding the second semiconductor die stack DS2. The first molding layer 150a may include a first molding material 151a and a plurality of first fillers 152a, and the second molding layer 250a may include a second molding material 251a and a plurality of second fillers 252a. As with the first molding layer 150 and the second molding layer 250 illustrated in FIG. 1 and FIG. 2, the thermal expansion coefficient of the second molding layer 250a may be lower than that of the first molding layer 150a.

According to an example embodiment, the average diameter of the plurality of first fillers 152a and the average diameter of the plurality of second fillers 252a may be substantially identical. Further, the content of the plurality of first fillers 152a and the content of the plurality of second fillers 252a may also be substantially identical.

However, the thermal expansion coefficient of the second molding material 251a embedding the plurality of second fillers 252a may be lower than the thermal expansion coefficient of the first molding material 151a embedding the plurality of first fillers 152a. The thermal expansion coefficient of the second molding layer 250a located close to the redistribution structure 400, which has a relatively large degree of thermal expansion due to its thick thickness, may be lower than the thermal expansion coefficient of the first molding layer 150a, which is located close to the intermediate redistribution structure 300, which has a relatively thin thickness. Since the second molding layer 250a is in direct contact with the intermediate redistribution structure 300 and the first molding layer 150a is in direct contact with the redistribution structure 400, the strain due to thermal stress of the intermediate redistribution structure 300 and the redistribution structure 400 may be reduced by the first molding layer 150a and the second molding layer 250a.

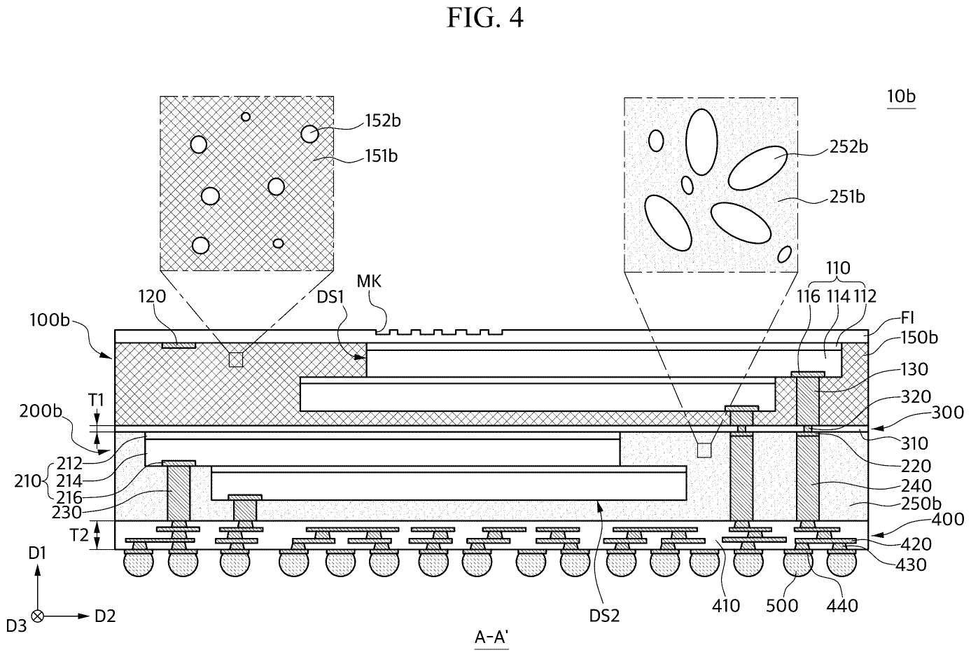

FIG. 4 is a drawing illustrating a semiconductor package according to an example embodiment, and illustrating a cross-section taken along line A-A′ of FIG. 1.

A semiconductor package 10b illustrated in FIG. 4 is almost identical or similar to the semiconductor package 10 illustrated in FIG. 1 and FIG. 2 except for the difference between a first molding layer 150b and a second molding layer 250b. Repetitive description on the elements mentioned with reference to FIG. 1 and FIG. 2 will be omitted or simplified below.

According to an example embodiment, a first package structure 100b of the semiconductor package 10b may include the first molding layer 150b surrounding the first semiconductor die stack DS1. A second package structure 200b of the semiconductor package 10b may include the first molding layer 150b surrounding the second semiconductor die stack DS2. The first molding layer 150b may include a first molding material 151b and a plurality of first fillers 152b, and the second molding layer 250b may include a second molding material 251b and a plurality of second fillers 252b. As with the first molding layer 150 and the second molding layer 250 illustrated in FIG. 1 and FIG. 2, the thermal expansion coefficient of the second molding layer 250b may be lower than the thermal expansion coefficient of the first molding layer 150b.

According to an example embodiment, unlike the plurality of second fillers 252 illustrated in FIG. 1 and FIG. 2, the plurality of second fillers 252b illustrated in FIG. 4 may not be spherical in shape. For example, the plurality of second fillers 252b illustrated in FIG. 4 may be ellipsoids. Here, the average size of the plurality of second fillers 252b may be larger than the average size of the plurality of first fillers 152b. Here, the size means volume. The average size of the plurality of second fillers 252b being larger than the average size of the plurality of first fillers 152b may indicate that the content of plurality of second fillers 252b is greater than the content of plurality of first fillers 152b. According to an example embodiment, the number of the plurality of first fillers 152b may be greater than the number of the plurality of second fillers 252b, but the total content of plurality of first fillers 152b is less than the total content of plurality of second fillers 252b.

According to an example embodiment, the thermal expansion coefficient of the second molding layer 250b located close to the redistribution structure 400, which has a relatively large thermal expansion due to its thick thickness, may be lower than the thermal expansion coefficient of the first molding layer 150b, which is located close to the intermediate redistribution structure 300, which has a relatively thin thickness. Since the second molding layer 250b is in direct contact with the intermediate redistribution structure 300 and the first molding layer 150b is in direct contact with the redistribution structure 400, the strain caused by thermal stress of the intermediate redistribution structure 300 and the redistribution structure 400 may be reduced by the first molding layer 150b and the second molding layer 250b.

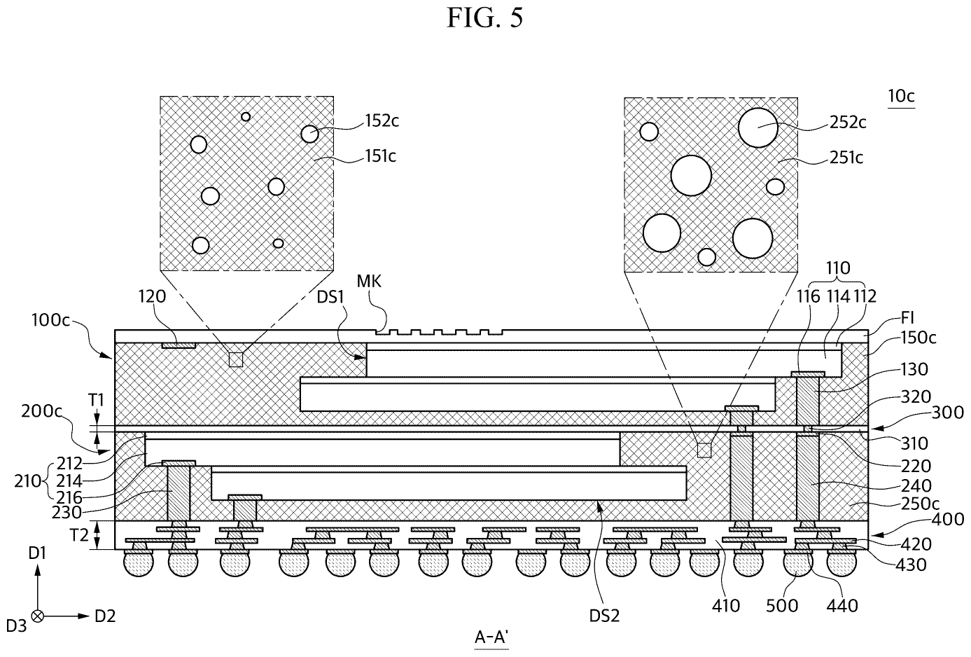

FIG. 5 is a drawing illustrating a semiconductor package according to an example embodiment, and illustrating a cross-section taken along line A-A′ of FIG. 1.

A semiconductor package 10c illustrated in FIG. 5 is almost identical or similar to the semiconductor package 10 illustrated in FIG. 1 and FIG. 2 except for the difference between a first molding layer 150c and a second molding layer 250c. Repetitive description on the elements mentioned with reference to FIG. 1 and FIG. 2 will be omitted or simplified.

According to an example embodiment, a first package structure 100c of the semiconductor package 10c may include the first molding layer 150c surrounding the first semiconductor die stack DS1. A second package structure 200c of the semiconductor package 10c may include the second molding layer 250c surrounding the second semiconductor die stack DS2. The first molding layer 150c may include a first molding material 151c and a plurality of first fillers 152c, and the second molding layer 250c may include a second molding material 251c and a plurality of second fillers 252c. As with the first molding layer 150c and the second molding layer 250c illustrated in FIG. 1 and FIG. 2, the thermal expansion coefficient of the second molding layer 250c may be lower than thermal expansion coefficient of the first molding layer 150c.

According to an example embodiment, the first molding material 151c and the second molding material 251c may be substantially the same materials. However, the average diameter of the plurality of second fillers 252c may be larger than the average diameter of the plurality of first fillers 152c. Further, the content of plurality of second fillers 252c may be greater than the content of plurality of first fillers 152c. The thermal expansion coefficient of the first filler 152c and the second filler 252c may be lower than the thermal expansion coefficient of the first molding material 151c and the second molding material 251c. Therefore, when the first molding material 151c and the second molding material 251c are substantially the same materials, the high filler content lowers the thermal expansion coefficient of the molding layer.

According to an example embodiment, the thermal expansion coefficient of the second molding layer 250c, located close to the redistribution structure 400, which has a relatively large degree of thermal expansion due to its thick thickness, may be lower than the thermal expansion coefficient of the first molding layer 150c, which is located close to the relatively thin intermediate redistribution structure 300. Since the second molding layer 250c is in direct contact with the intermediate redistribution structure 300 and the first molding layer 150c is in direct contact with the redistribution structure 400, the strain due to thermal stress of the intermediate redistribution structure 300 and the redistribution structure 400 may be reduced by the first molding layer 150c and the second molding layer 250c.

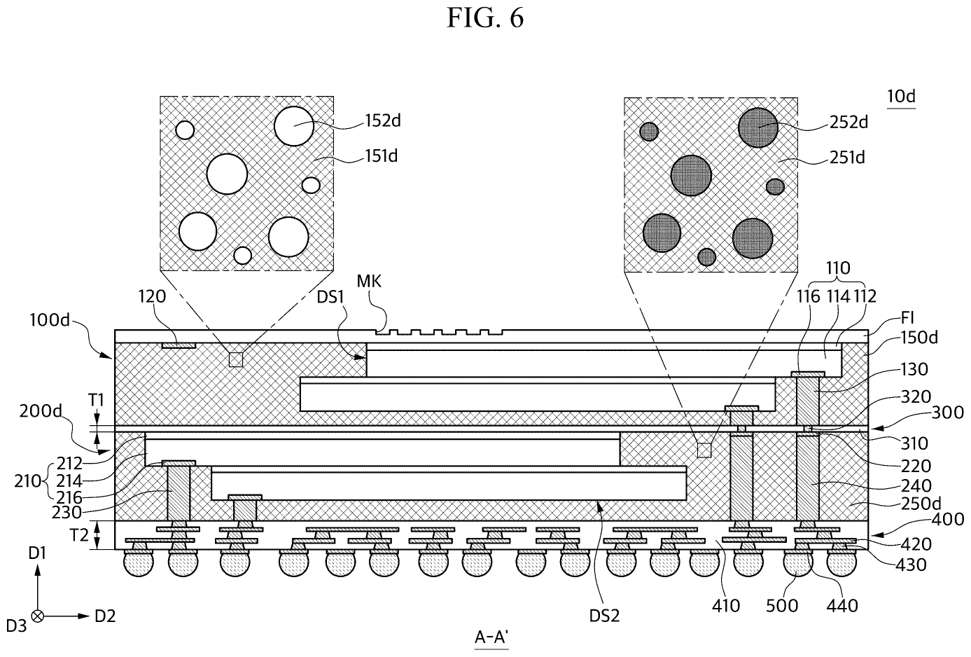

FIG. 6 is a drawing illustrating a semiconductor package according to an example embodiment, and illustrating a cross-section taken along line A-A′ of FIG. 1.

A semiconductor package 10d illustrated in FIG. 6 is almost identical or similar to the semiconductor package 10 illustrated in FIG. 1 and FIG. 2 except for the difference between a first molding layer 150d and a second molding layer 250d. Repetitive description on the elements mentioned with reference to FIG. 1 and FIG. 2 will be omitted or simplified.

According to an example embodiment, a first package structure 100d of the semiconductor package 10d may include the first molding layer 150d surrounding the first semiconductor die stack DS1. A second package structure 200d of the semiconductor package 10d may include the first molding layer 150d surrounding the second semiconductor die stack DS2. The first molding layer 150d may include a first molding material 151d and a plurality of first fillers 152d, and the second molding layer 250d may include a second molding material 251d and a plurality of second fillers 252d. As with the first molding layer 150 and the second molding layer 250 illustrated in FIG. 1 and FIG. 2, the thermal expansion coefficient of the second molding layer 250d may be lower than the thermal expansion coefficient of the first molding layer 150d.

According to an example embodiment, the first molding material 151d and the second molding material 251d may be substantially the same materials. The average diameter of the plurality of first fillers 152d may be substantially equal to the average diameter of the plurality of second fillers 252d. Further, the content of the plurality of first fillers 152d may be substantially identical to the content of the plurality of second fillers 252d.

According to an example embodiment, the substances constituting the plurality of first fillers 152d and the substances constituting the plurality of second fillers 252d may be different from each other. The thermal expansion coefficient of the material constituting the plurality of second fillers 252d may be lower than the thermal expansion coefficient of the material constituting the plurality of first fillers 152d. Therefore, the thermal expansion coefficient of the second molding layer 250d including the plurality of second fillers 252d may be lower than the thermal expansion coefficient of the first molding layer 150d including the plurality of first fillers 152d.

According to an example embodiment, the thermal expansion coefficient of the second molding layer 250d located close to the redistribution structure 400, which is thick and has relatively large thermal expansion, may be lower than the thermal expansion coefficient of the first molding layer 150d, which is located close to the intermediate redistribution structure 300, which has a relatively thin thickness. Since the second molding layer 250d is in direct contact with the intermediate redistribution structure 300 and the first molding layer 150d is in direct contact with the redistribution structure 400, the strain due to thermal stress of the intermediate redistribution structure 300 and the redistribution structure 400 may be reduced by the first molding layer 150d and the second molding layer 250d.

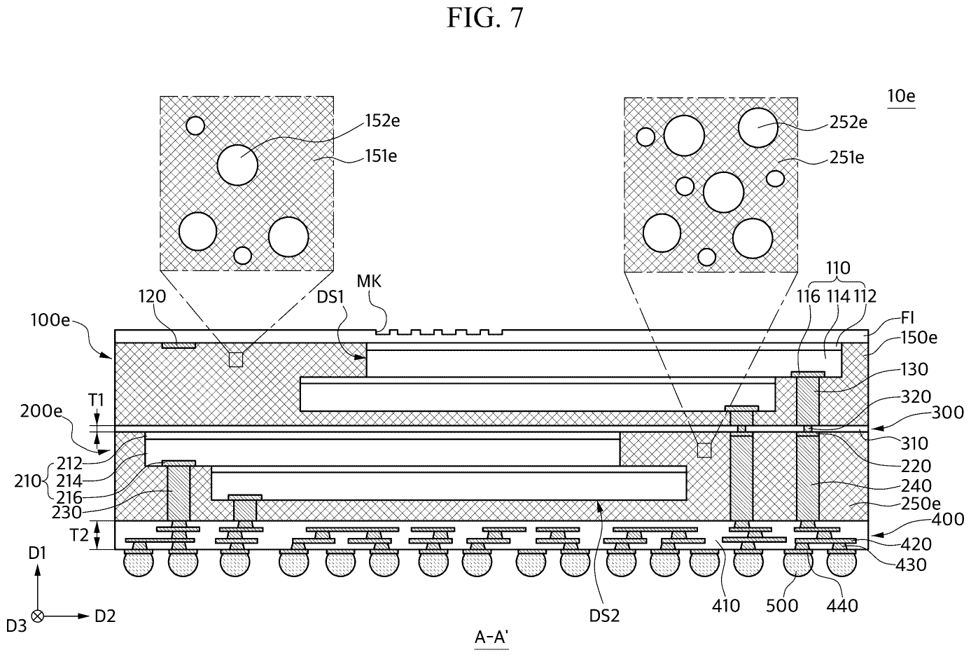

FIG. 7 is a drawing illustrating a semiconductor package according to an example embodiment, and illustrating a cross-section taken along line A-A′ of FIG. 1.

A semiconductor package 10e illustrated in FIG. 7 is almost identical or similar to the semiconductor package 10 illustrated in FIG. 1 and FIG. 2 except for the difference between a first molding layer 150e and a second molding layer 250e. Repetitive description on the elements mentioned with reference to FIG. 1 and FIG. 2 will be omitted or simplified.

According to an example embodiment, a first package structure 100e of the semiconductor package 10e may include the first molding layer 150e surrounding the first semiconductor die stack DS1. A second package structure 200e of the semiconductor package 10e may include the second molding layer 250e surrounding the second semiconductor die stack DS2. The first molding layer 150e may include a first molding material 151e and a plurality of first fillers 152e, and the second molding layer 250e may include a second molding material 251e and a plurality of second fillers 252e. As with the first molding layer 150 and the second molding layer 250 illustrated in FIG. 1 and FIG. 2, the thermal expansion coefficient of the second molding layer 250e may be lower than the thermal expansion coefficient of the first molding layer 150e.

According to an example embodiment, the first molding material 151e and the second molding material 251e may be substantially the same materials. Further, the average diameter of the plurality of first fillers 152e may be substantially equal to the average diameter of the plurality of second fillers 252e. However, the content of plurality of first fillers 152e may be less than the content of plurality of second fillers 252e.

According to an example embodiment, the thermal expansion coefficient of the first filler 152e and the second filler 252e may be lower than the thermal expansion coefficient of the first molding material 151e and the second molding material 251e. Therefore, when the first molding material 151e and the second molding material 251e are substantially the same material and have the same average diameter, as the filler content increases, the thermal expansion coefficient of the molding layer decreases. Since the content of the second filler 252e is higher than the content of the first filler 152e, the thermal expansion coefficient of the second molding layer 250e may be lower than the thermal expansion coefficient of the first molding layer 150e.

According to an example embodiment, the thermal expansion coefficient of the second molding layer 250e, located close to the redistribution structure 400, which has a relatively large thermal expansion due to its thick thickness, may be lower than the thermal expansion coefficient of the first molding layer 150e, which is located close to the intermediate redistribution structure 300, which has a relatively thin thickness. Since the second molding layer 250e is in direct contact with the intermediate redistribution structure 300 and the first molding layer 150e is in direct contact with the redistribution structure 400, the strain due to thermal stress of the intermediate redistribution structure 300 and the redistribution structure 400 may be reduced by the first molding layer 150e and the second molding layer 250e.

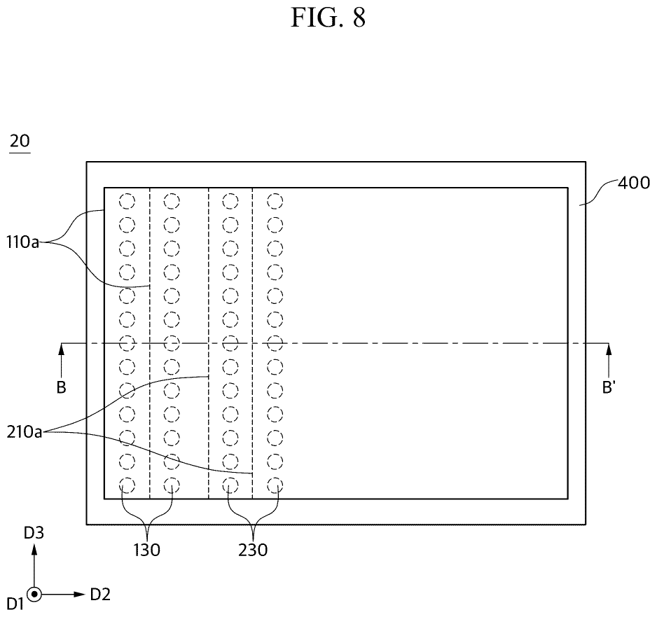

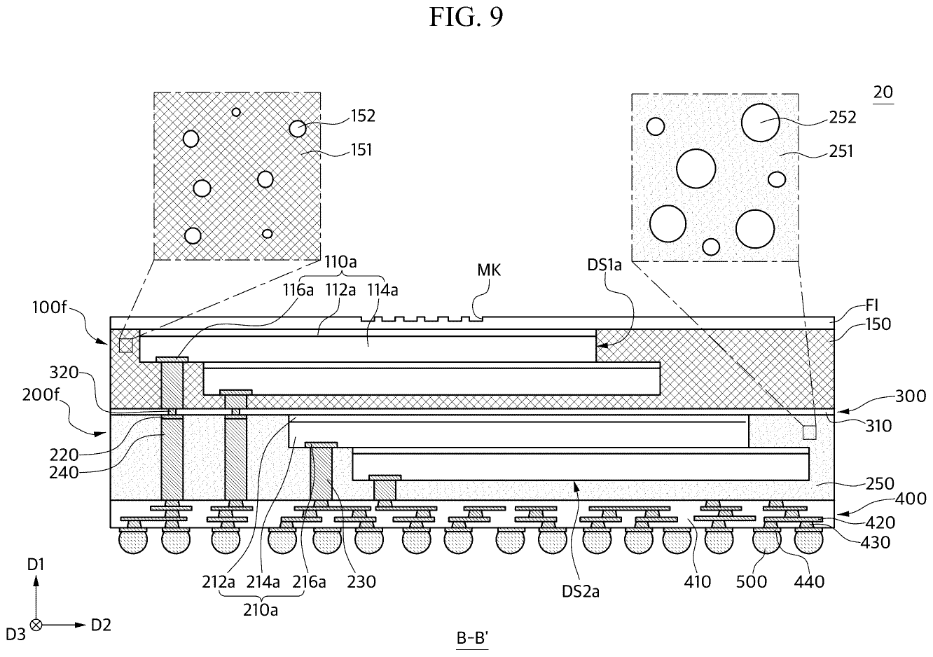

FIG. 8 is a schematic plan view illustrating a semiconductor package according to another example embodiment, and FIG. 9 is a drawing illustrating a cross-section taken along line B-B′ of FIG. 8.

A semiconductor package 20 illustrated in FIG. 8 and FIG. 9 is almost identical or similar to the semiconductor package 10 illustrated in FIG. 1 and FIG. 2 except that the direction in which a plurality of first semiconductor dies 110a are offset and the direction in which a plurality of second semiconductor dies 210a offset are identical to each other. Repetitive description on the elements mentioned with reference to FIG. 1 and FIG. 2 will be omitted or simplified.

According to an example embodiment, the plurality of first semiconductor dies 110a constituting a first semiconductor die stack DS1a may be stacked in a step manner in the first direction D1. The plurality of first semiconductor dies 110a stacked in a step structure may be arranged offset from each other along the reverse direction −D2 of the second direction. For example, among the plurality of first semiconductor dies 110a, the first semiconductor die 110a placed on the top may be misaligned in the reverse direction −D2 of the second direction with respect to the first semiconductor die 110a placed on the bottom.

According to an example embodiment, the plurality of second semiconductor dies 210a constituting a second semiconductor die stack DS2a may also be stacked in a step structure in the first direction D1. The plurality of first semiconductor dies 110a stacked in the step structure may also be arranged offset from each other along the reverse direction −D2 of the second direction. For example, among the plurality of second semiconductor dies 210a, the second semiconductor die 210a placed on the top may be misaligned in the reverse direction −D2 of the second direction with respect to the second semiconductor die 210a placed on the bottom. Further, among the plurality of second semiconductor dies 210a, the first semiconductor die 110a located at the bottom may be misaligned in the reverse direction −D2 of the second direction with respect to the second semiconductor die 210a located at the top. In the example embodiment, even though the direction in which a plurality of semiconductor dies (the first semiconductor die 110a and the second semiconductor die 210a) are offset is defined as the reverse direction −D2 of the second direction, according to an example embodiment, the direction in which a plurality of semiconductor dies (the first semiconductor die 110a and the second semiconductor die 210a) are offset may be other than the reverse direction −D2 of the second direction. Even in this case, the point or the fact that the directions in which the plurality of semiconductor dies (the first semiconductor die 110a and the second semiconductor die 210a) are offset are unified with each other may not be changed.

According to an example embodiment, within a second package structure 200f, the plurality of second conductive posts 230 and a plurality of second through posts 240 may be arranged in the reverse direction −D2 of the second direction or in the second direction D2. Since a plurality of first connection pads 116a and a plurality of second connection pads 216a are arranged in the reverse direction D2 or in the second direction D2, the plurality of second conductive posts 230 and the plurality of second through posts 240 are also arranged in a row in the reverse direction of the second direction D2 or in the second direction D2.

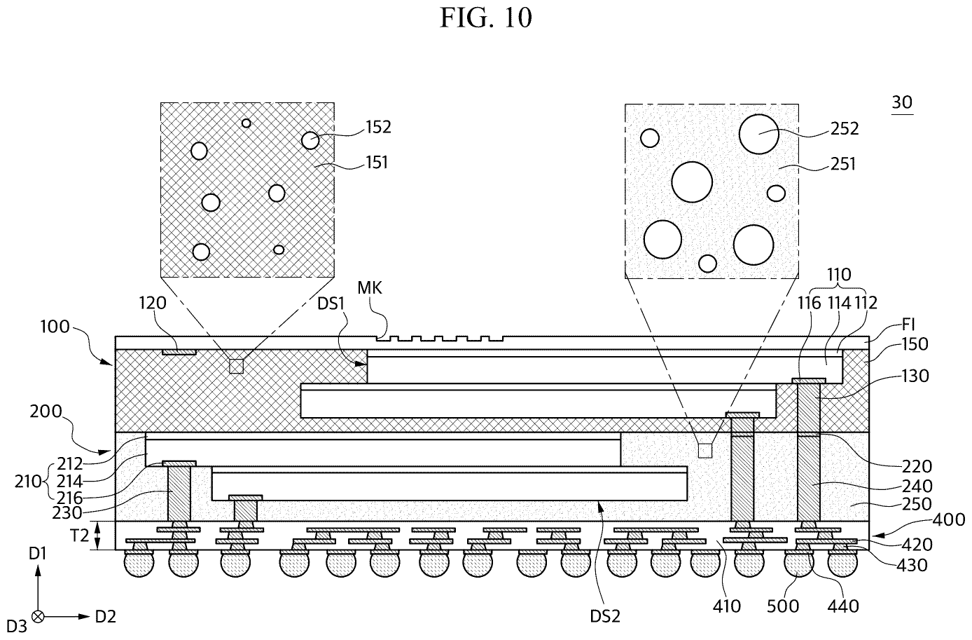

FIG. 10 is a schematic cross-sectional diagram illustrating a semiconductor package according to another example embodiment.

A semiconductor package 30 illustrated in FIG. 10 is almost identical or similar to the semiconductor package 10 illustrated in FIG. 1 and FIG. 2 except that the semiconductor package 30 does not include the intermediate redistribution structure 300 (see FIG. 2). Repetitive description on the elements mentioned with reference to FIG. 1 and FIG. 2 will be omitted or simplified.

According to an example embodiment, the semiconductor package 30 may not have a redistribution structure placed between the first package structure 100 and the second package structure 200. The second adhesive layer 212 of the second semiconductor die 210 located at the uppermost layer among the plurality of second semiconductor dies 210 may be in direct contact with the first molding layer 150. The second adhesive layer 212 may extend along the front side of the first molding layer 150. Further, the back side of the second molding layer 250 may be in direct contact with the front side of the first molding layer 150. The plurality of second through posts 240 are in direct contact with the first connection pad 220, and the first connection pad 220 is in direct contact with the plurality of first conductive posts 130.

According to an example embodiment, the thermal expansion coefficient of the second molding layer 250 may be lower than the thermal expansion coefficient of the first molding layer 150. The thermal expansion coefficient of the redistribution structure 400 may be higher than the thermal expansion coefficient of the first molding layer 150 and the thermal expansion coefficient of the second molding layer 250. The thermal expansion coefficient of the second molding layer 250 located close to the redistribution structure 400, which has relatively large thermal expansion, may be lower than the thermal expansion coefficient of the first molding layer 150, which is located far from the redistribution structure 400. Since the first molding layer 150, which has a low thermal expansion coefficient, is in direct contact with the redistribution structure 400, the strain caused by thermal stress of the redistribution structure 400 may be reduced by the first molding layer 150.

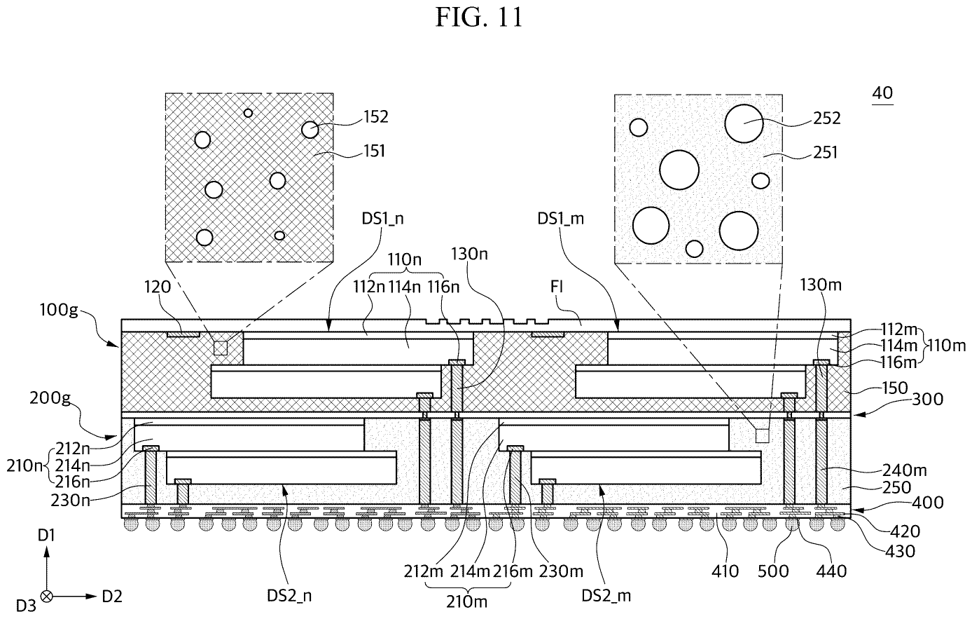

FIG. 11 is a schematic cross-sectional diagram illustrating a semiconductor package according to another example embodiment.

A semiconductor package 40 illustrated in FIG. 11 is almost identical or similar to the semiconductor package 10 illustrated in FIG. 1 and FIG. 2 except that a first package structure 100g and a second package structure 200g include a plurality of first semiconductor die stacks DS1_n and DS1_m and a plurality of second semiconductor die stacks DS2_n and DS2_m. Repetitive description on the elements mentioned with reference to FIG. 1 and FIG. 2 will be omitted or simplified.

According to an example embodiment, the first package structure 100g may include the plurality of first semiconductor dies stacks DS1_n and DS1_m. The plurality of first semiconductor dies stacks DS1_n and DS1_m may be arranged side by side along the horizontal direction (the second direction D2 in this example embodiment). Each of the plurality of first semiconductor dies stacks DS1_n and DS1_m may include a first adhesive layer (a first adhesive layer 112n and a first adhesive layer 112m), a first chip body (a first chip body 114n and a first chip body 114m), and a first connection pad (a first connection pad 116n and a first connection pad 116m).

According to an example embodiment, the first package structure 100g may include a plurality of first conductive posts (a first conductive post 130n and a first conductive post 130m). Each of the plurality of first conductive posts (the first conductive post 130n and the first conductive post 130m) may be connected to the first connection pad (the first connection pad 116n and the first connection pad 116m) and the intermediate redistribution structure 300. Each of the plurality of first conductive posts (the first conductive post 130n and the first conductive post 130m) may electrically connect between a first semiconductor die (a first semiconductor die 110n and a first semiconductor die 110m) and the intermediate redistribution structure 300.

According to an example embodiment, the second package structure 200g may include a plurality of second semiconductor dies stack DS2. The plurality of second semiconductor die stacks DS2_n and DS2_m may be arranged side by side in the horizontal direction (the second direction D2 in the example embodiment). Each of the plurality of second semiconductor die stacks DS2_n and DS2_m may include a second adhesive layer (a second adhesive layer 212n and a second adhesive layer 212m), a second chip body (a second chip body 214n and a second chip body 214m), and a second connection pad (a second connection pad 216n and a second connection pad 216m).

According to an example embodiment, the second package structure 200g may include a plurality of second conductive posts 230n and 230m and a plurality of second through posts 240n and 240m. Each of the plurality of second conductive posts 230n and 230m may be connected to a second connection pad (the second connection pad 216n and the second connection pad 216m) and the redistribution structure 400. Each of the plurality of second conductive posts 230n and 230m may electrically connect between a second semiconductor die (a second semiconductor die 210n and a second semiconductor die 210m) and the redistribution structure 400. The plurality of second through posts 240n and 240m may electrically connect between the redistribution structure 400 and the intermediate redistribution structure 300.

The first semiconductor die stacks DS1_n and DS1_m, the second semiconductor die stacks DS2_n and DS2_m, the first conductive post 130n and the first conductive post 130m, the second conductive posts 230n and 230m, and the second through posts 240n and 240m illustrated in FIG. 11 may be substantially identical to the first semiconductor die stack DS1, the second semiconductor die stack DS2, the first conductive post 130, the second conductive post 230, and the second through post 240 illustrated in FIG. 1 and FIG. 2. Therefore, specific descriptions on the elements listed above are omitted below.

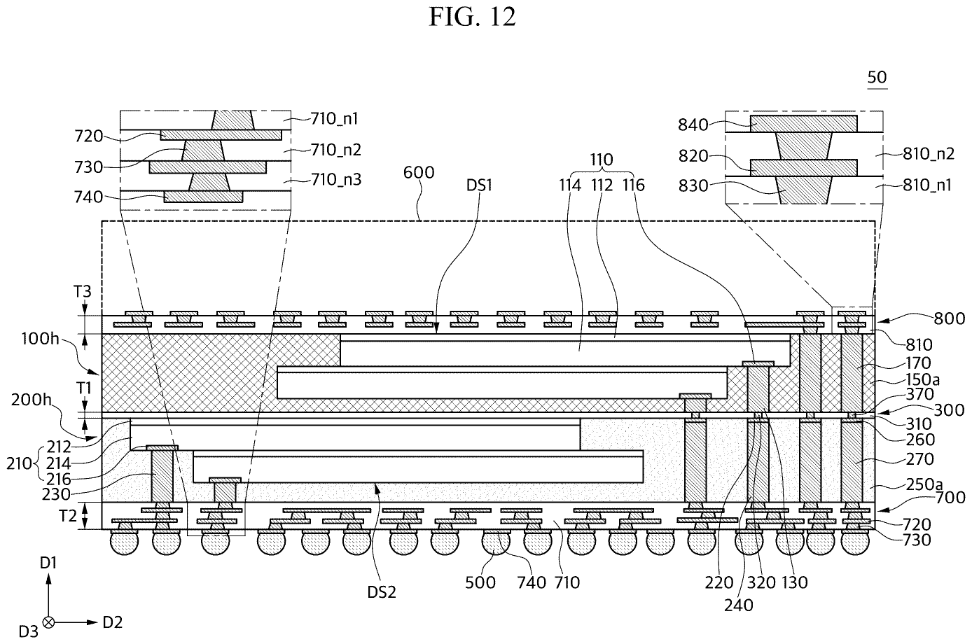

FIG. 12 is a schematic cross-sectional diagram illustrating a semiconductor package according to another example embodiment.

A semiconductor package 50 illustrated in FIG. 12 is almost identical or similar to the semiconductor package 10 illustrated in FIG. 1 and FIG. 2 except that the semiconductor package 50 includes a second redistribution structure 800, a first through post 170, and a third through post 270. Repetitive description on the elements mentioned with reference to FIG. 1 and FIG. 2 will be omitted or simplified. In the example embodiment, the expression “first” in defining the first through post 170 refers to the configuration included in the first package structure 100h.

According to an example embodiment, the semiconductor package 50 may include a first package structure 100h and a second package structure 200h that are spaced apart from each other in the first direction D1 with the intermediate redistribution structure 300 interposed therebetween. The first package structure 100h may include the first semiconductor die stack DS1, the first conductive post 130, the first through post 170, and the first molding layer 150. The first semiconductor die stack DS1, the first conductive post 130, and the first molding layer 150 are substantially identical to the first semiconductor die stack DS1, the first conductive post 130, and the first molding layer 150 illustrated in FIG. 1 and FIG. 2, and thus detailed descriptions are omitted. The first molding layer 150 may surround the first semiconductor die stack DS1, the first conductive post 130, and the first through post 170.

According to an example embodiment, the first through post 170 may be connected to the intermediate redistribution structure 300 and the second redistribution structure 800. Specifically, the first through post 170 may be connected to the first intermediate redistribution via 320 and a second intermediate redistribution via 370 of the intermediate redistribution structure 300 and a second redistribution via 830 of the second redistribution structure 800 in order to electrically connect the second redistribution structure 800 and the intermediate redistribution structure 300. According to an example embodiment, not the first intermediate redistribution via 320 and the second intermediate redistribution via 370 or the second redistribution via 830, the first through post 170 may be connected to a conductive pad that interfaces with the first intermediate redistribution via 320 and the second intermediate redistribution via 370, or to a conductive pad that interfaces with the second redistribution via 830.

According to an example embodiment, a first redistribution structure 700 may be placed on the front side of the second package structure 200h. The back side of the second package structure 200h refers to the side facing the intermediate redistribution structure 300, and the front side of the second package structure 200h refers to the side opposite to the front side. The first redistribution structure 700 may include a first redistribution insulation layer 710, a first redistribution pattern 720, a first redistribution via 730, and a first redistribution pad 740. The first redistribution structure 700 may be substantially identical to the redistribution structure 400 illustrated in FIG. 1 and FIG. 2 except that the first redistribution structure 700 is connected to the third through post 270. The second molding layer 250 may surround the second semiconductor die stack DS2, the second conductive post 230, the second through post 240, and the third through post 270.

According to an example embodiment, the second package structure 200h may include the second semiconductor die stack DS2, the second conductive post 230, the second through post 240, the third through post 270, and the second molding layer 250. The second semiconductor die stack DS2, the second conductive post 230, and the second molding layer 250 are substantially identical to the second semiconductor die stack DS2, the second conductive post 230, and the second molding layer 250 illustrated in FIG. 1 and FIG. 2, and thus detailed descriptions are omitted. Further, the second through post 240 may be substantially identical to the second through post 240 illustrated in FIG. 1 and FIG. 2.

According to an example embodiment, like the second through post 240 illustrated in FIG. 1 and FIG. 2, the second through post 240 may be connected to the first connection pad 220 and the first redistribution structure 700. The third through post 270 may be connected to the intermediate redistribution structure 300 and the first redistribution structure 700. Specifically, the third through post 270 is connected to a second connection pad 260 and the first redistribution via 730 of the first redistribution structure 700 in order to electrically connect the intermediate redistribution structure 300 and the first redistribution structure 700. According to an example embodiment, the third through post 270 may be connected to a conductive pad that interfaces with the first redistribution via 730, not the first redistribution via 730.

According to an example embodiment, the intermediate redistribution structure 300 may have the first thickness T1 in the first direction D1, the first redistribution structure 700 may have the second thickness T2, and the second redistribution structure 800 may have the third thickness T3. The second thickness T2 may be greater than the third thickness T3, and the third thickness T3 may be larger than the first thickness T1.

According to an example embodiment, the first redistribution structure 700 may include a plurality of first redistribution insulation layers 710_n1, 710_n2 and 710_n3 arranged in a multi-layer structure. The first redistribution insulation layers 710_n1, 710_n2 and 710_n3 may also be referred to as laminated redistribution insulation layers. The first redistribution insulation layers 710_n1, 710_n2 and 710_n3 may be laminated in the first direction D1. In the example embodiment, the first redistribution insulation layers 710_n1, 710_n2 and 710_n3 are depicted as a three-stage structure. However, the present disclosure is not limited thereto, and the first redistribution insulation layers may have a three or more-layer laminated structure. In the present disclosure, a higher number of insulation layers indicates a thicker redistribution structure.

According to an example embodiment, the first redistribution pattern 720 may be placed on the front side of the first redistribution insulation layers 710_n1, 710_n2 and 710_n3 which are in a multilayer structure. The first redistribution via 730 may connect a plurality of first redistribution patterns 720 arranged spaced apart from each other in the first direction D1. The first redistribution via 730 may be connected to the first redistribution pattern 720 at a different level in the first direction D1 by penetrating one of the first redistribution insulation layers 710_n1, 710_n2 and 710_n3.

According to an example embodiment, the second redistribution structure 800 may include a plurality of second redistribution insulation layers 810_n1 and 810_n2 arranged in a multi-layer structure. The plurality of second redistribution insulation layers 810_n1 and 810_n2 may be referred to as a laminated redistribution insulation layer. The plurality of second redistribution insulation layers 810_n1 and 810_n2 may be laminated in the first direction D1. In the example embodiment, the plurality of second redistribution insulation layers 810_n1 and 810_n2 are depicted as a two-stage structure. However, the present disclosure is not limited thereto, and the plurality of second redistribution insulation layers may have a laminated structure of two or more layers. The number of second redistribution insulation layers may be smaller than the number of first redistribution insulation layers. In other words, the total thickness of the plurality of second redistribution insulation layers may be thinner than the sum of the thicknesses of first redistribution insulation layers.

According to an example embodiment, a second redistribution pattern 820 may be arranged on the back side of the plurality of second redistribution insulation layers 810_n1 and 810_n2 of the multilayer structure. The second redistribution via 830 may connect the second redistribution patterns 820 arranged spaced apart from each other along the first direction D1. The second redistribution via 830 may be connected to the second redistribution pattern 820 at a different level in the first direction D1 by penetrating through the second redistribution insulation layers 810_n1 and 810_n2.

According to an example embodiment, the number of plurality of second redistribution insulation layers (the second redistribution insulation layers 810_n1 and 810_n2) is smaller than the number of the first redistribution insulation layers (the first redistribution insulation layers 710_n1, 710_n2 and 710_n3), and thus the third thickness T3 of the second redistribution structure 800 may be smaller than the second thickness T2 of the first redistribution structure 700. The materials constituting the intermediate redistribution insulation layer 310, the first redistribution insulation layers 710_n1, 710_n2 and 710_n3, and the second redistribution insulation layers 810_n1 and 810_n2 may be substantially identical to one another.

As described above with reference to FIG. 1 and FIG. 2, the thermal expansion coefficient of the intermediate redistribution insulation layer 310, the first redistribution insulation layers 710_n1, 710_n2 and 710_n3, and the second redistribution insulation layers 810_n1 and 810_n2 may be greater than the thermal expansion coefficient of the first molding layer 150 and the second molding layer 250. As the thickness of the intermediate redistribution structure 300, the first redistribution structure 700 and the second redistribution structure 800 increase, the degree of expansion due to thermal energy may relatively increase. The thicker the redistribution structure, the greater the content of the redistribution insulation layer, and thus the degree of bending due to thermal energy may be large. When the thickness of the redistribution insulation layer is thin, it is difficult to strain the shape of the molding layer despite thermal expansion due to the relatively high stiffness of the molding layer. When the redistribution insulation layer is thick enough, sufficient thermal stress may be applied to strain the shape of the molding layer despite the stiffness of the molding layer. Thus, the warpage may occur in the semiconductor package 50.

According to an example embodiment, since the thickness of the first redistribution structure 700 is thicker than the thickness of the second redistribution structure 800, the thermal expansion coefficient of the second molding layer 250, which is the molding layer closest to the first redistribution structure 700, may be lower than the thermal expansion coefficient of the first molding layer 150. The first molding layer 150 may reduce the strain due to the tensile stress of the first redistribution structure 700 that is heated by being in direct contact with the first redistribution structure 700. The second molding layer 250 may reduce the strain caused by the tensile stress of the second redistribution structure 800 when heated by being in direct contact with the second redistribution structure 800.

According to an example embodiment, the semiconductor package 50 may further include a semiconductor device 600 mounted on the second redistribution structure 800. The semiconductor device 600 may be a semiconductor package including another semiconductor chip. The semiconductor device 600 may be mounted on the second redistribution structure 800 in a variety of ways. For example, the semiconductor device 600 may be mounted by flip chip bonding or wire bonding. In another example embodiment, the semiconductor device 600 may include an interposer, and the interposer may be mounted on the second redistribution structure 800. Since the semiconductor device 600 is mounted on the second redistribution structure 800, the semiconductor package 50 may have a package-on-package (POP) structure.

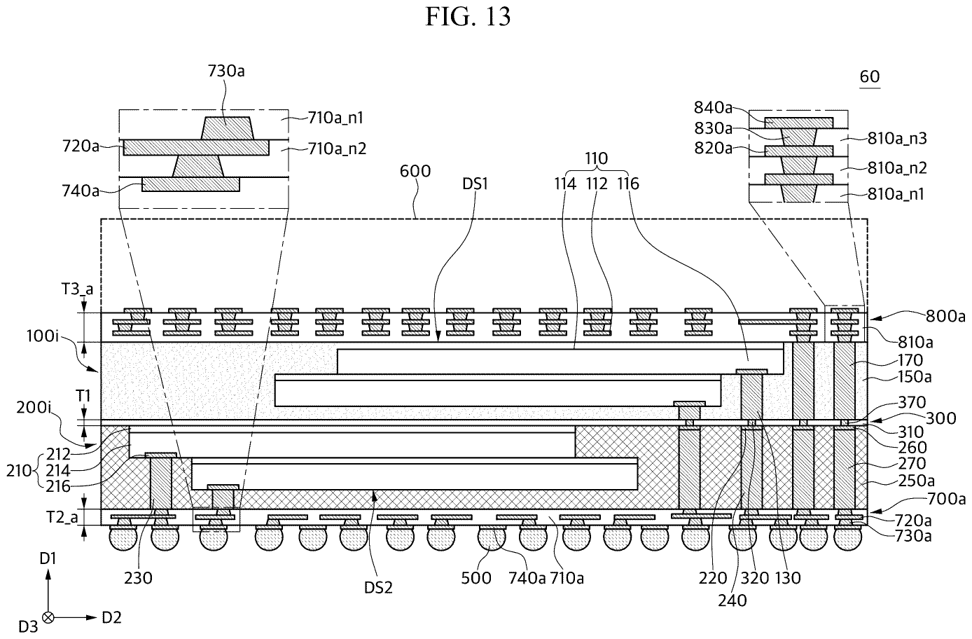

FIG. 13 is a schematic cross-sectional diagram illustrating a semiconductor package according to another example embodiment.

A semiconductor package 60 illustrated in FIG. 13 is almost identical or similar to the semiconductor package 50 illustrated in FIG. 12 except that the third thickness T3_a of a second redistribution structure 800a is thicker than the second thickness T2_a of a first redistribution structure 700a. Repetitive descriptions of elements mentioned with reference to FIG. 1, FIG. 2, and FIG. 12 will be omitted or simplified.

According to an example embodiment, the intermediate redistribution structure 300 may have the first thickness T1 in the first direction D1, the first redistribution structure 700a may have the second thickness T2_a, and the second redistribution structure 800a may have the third thickness T3_a. The third thickness T3_a may be greater than the second thickness T2_a and the second thickness T2_a may be greater than the first thickness T1_a.

According to an example embodiment, the first redistribution structure 700a may include a plurality of first redistribution insulation layers 710a_n1 and 710a_n2 arranged in a multi-layer structure. The plurality of first redistribution insulation layers 710a_n1 and 710a_n2 may be laminated in the first direction D1. In the example embodiment, the plurality of first redistribution insulation layers 710a_n1 and 710a_n2 are depicted as a two-stage structure. However, the present disclosure is not limited thereto. The plurality of first redistribution insulation layers may have a laminated structure of two or more layers. A first redistribution pattern 720a, a first redistribution via 730a, and a first redistribution pad 740a may be substantially identical to the first redistribution pattern 720, the first redistribution via 730, and the first redistribution pad 740 illustrated in FIG. 12.

According to an example embodiment, the second redistribution structure 800a may include a plurality of second redistribution insulation layers 810a_n1, 810a_n2 and 810a_n3 arranged in a multi-layer structure. The plurality of second redistribution insulation layers 810a_n1, 810a_n2 and 810a_n3 may be laminated in the first direction D1. In the example embodiment, the plurality of second redistribution insulation layers 810a_n1, 810a_n2 and 810a_n3 are depicted as a three-stage structure. However, the present disclosure is not limited thereto. The plurality of second redistribution insulation layers may have a laminated structure of three or more layers. However, the number of plurality of second redistribution insulation layers may be greater than the number of the plurality of first redistribution insulation layers. A second redistribution pattern 820a, a second redistribution via 830a, and a second redistribution pad 840a may be substantially identical to the second redistribution pattern 820, the second redistribution via 830 and a second redistribution pad 840 illustrated in FIG. 12.

According to an example embodiment, unlike the semiconductor package 50 of FIG. 12, the thermal expansion coefficient of the first molding layer 150a may be less than the thermal expansion coefficient of the second molding layer 250a. As the thickness of the intermediate redistribution structure 300, the first redistribution structure 700a and the second redistribution structure 800a increases, the degree of expansion due to thermal energy may relatively increase. The thicker the redistribution structure, the greater the content of the redistribution insulation layer, and thus the degree of bending due to thermal energy may be great.

According to an example embodiment, since the thickness of the second redistribution structure 800a is thicker than the thickness of the first redistribution structure 700a, the thermal expansion coefficient of the first molding layer 150a, which is the molding layer closest to the second redistribution structure 800a, may be lower than the thermal expansion coefficient of the second molding layer 250a. The first molding layer 150a may reduce the strain caused by the tensile stress of the second redistribution structure 800a, which is heated by being in direct contact with the second redistribution structure 800a. The second molding layer 250a may reduce the strain caused by the tensile stress of the first redistribution structure 700a that is heated by being in direct contact with the first redistribution structure 700a.

According to an example embodiment, as with the semiconductor package 50 illustrated in FIG. 12, the semiconductor package 60 may further include the semiconductor device 600 mounted on the second redistribution structure 800a. The description of the semiconductor device 600 overlaps with that described with reference to FIG. 12, and thus repetitive descriptions will be omitted.

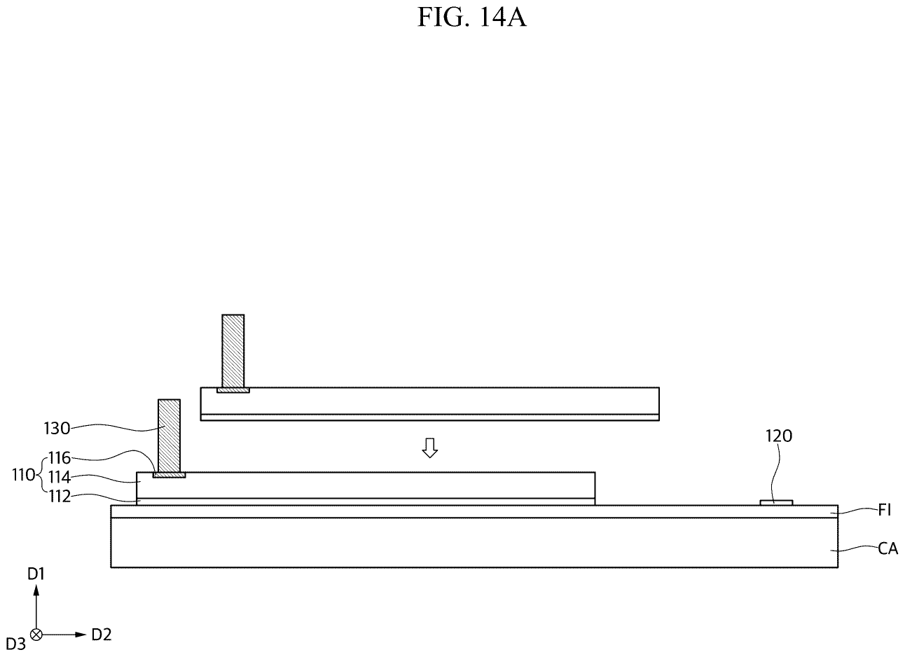

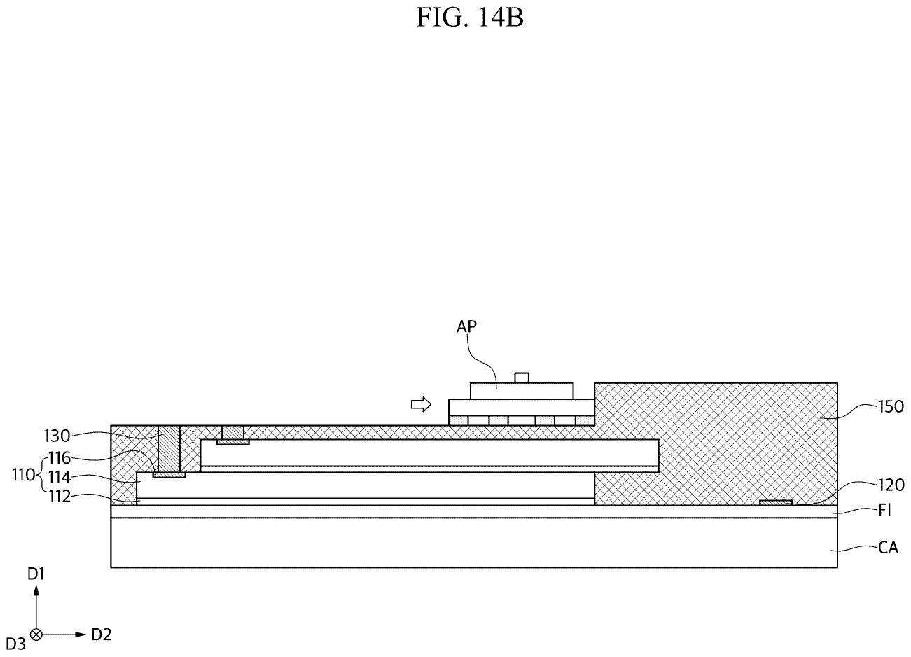

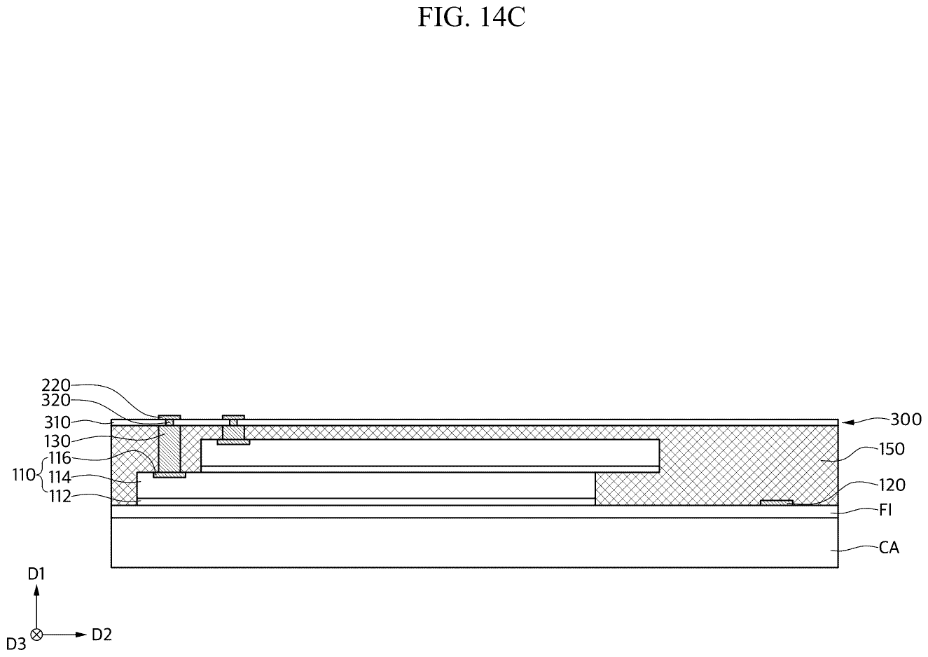

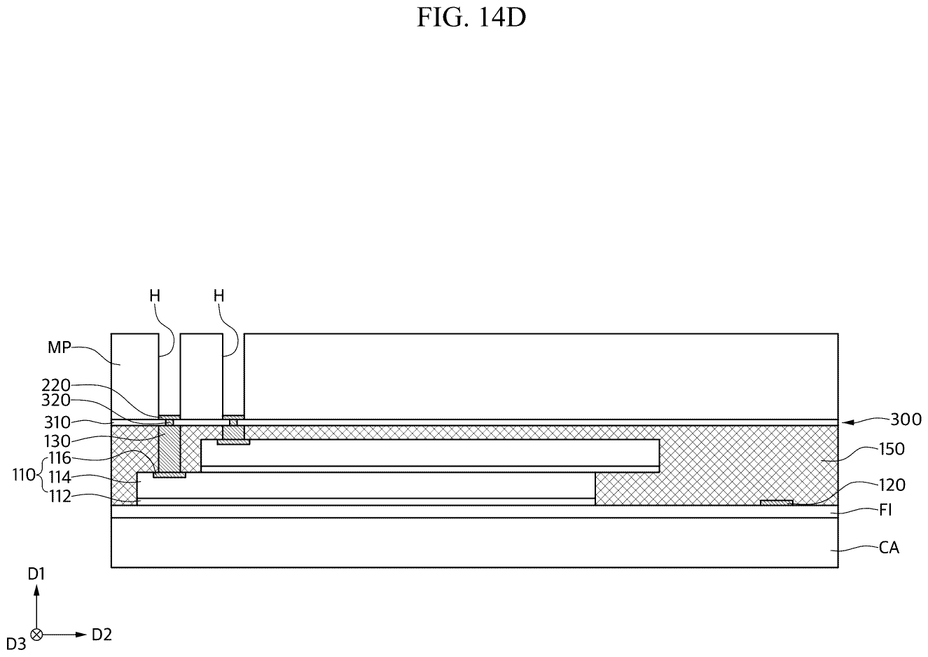

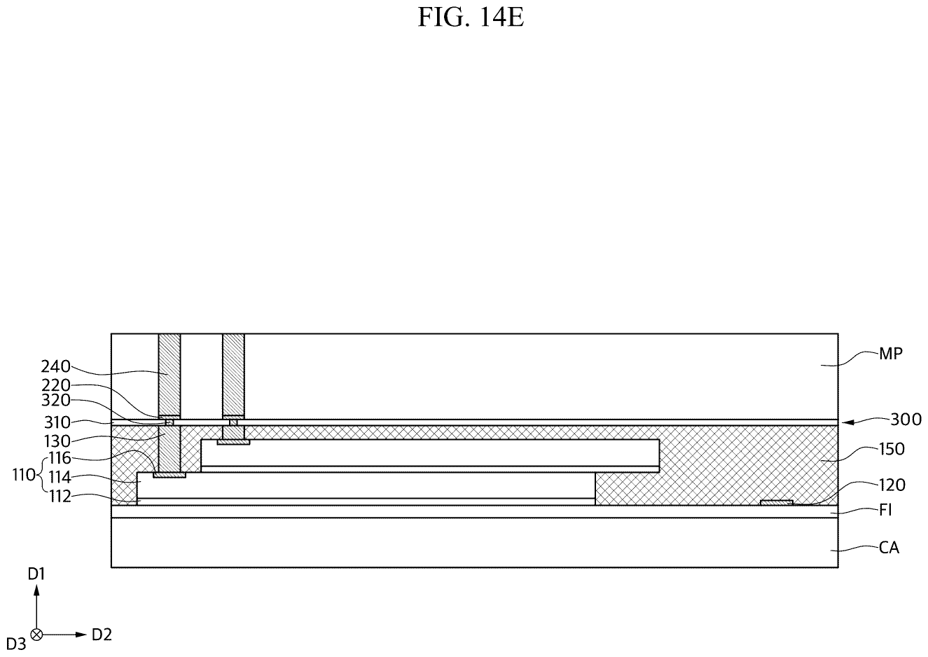

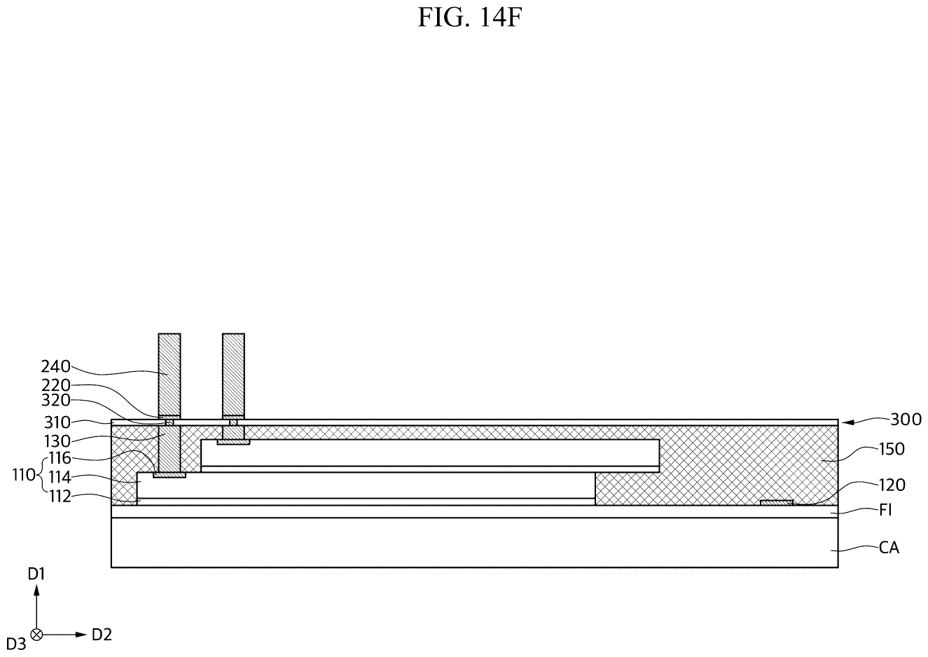

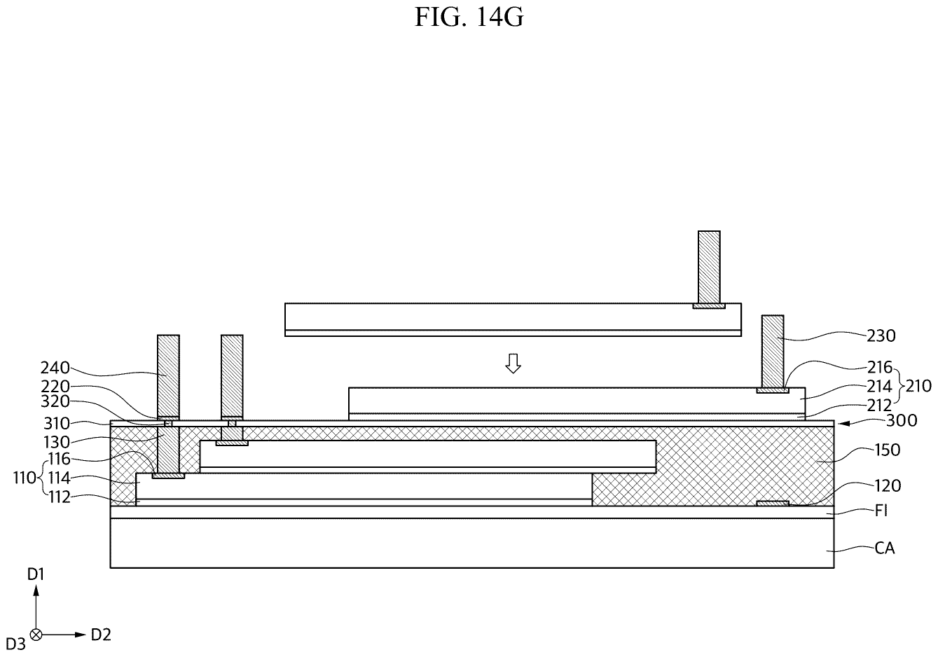

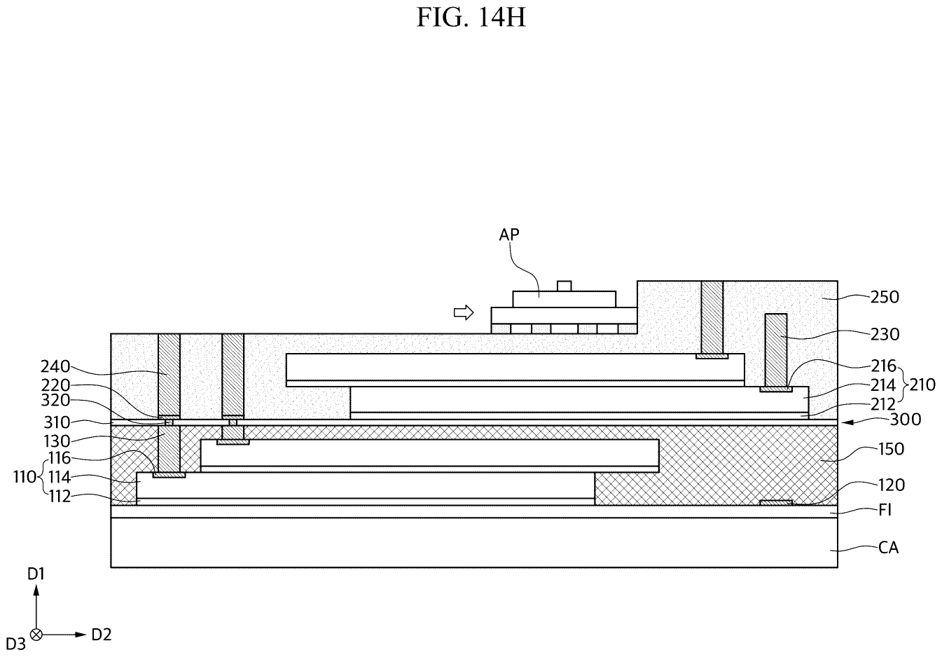

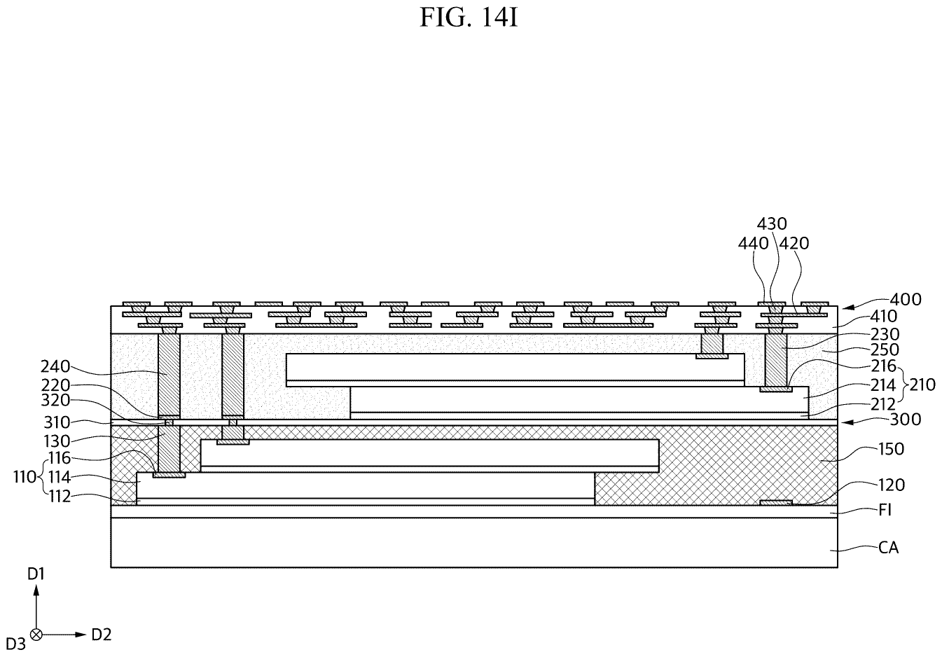

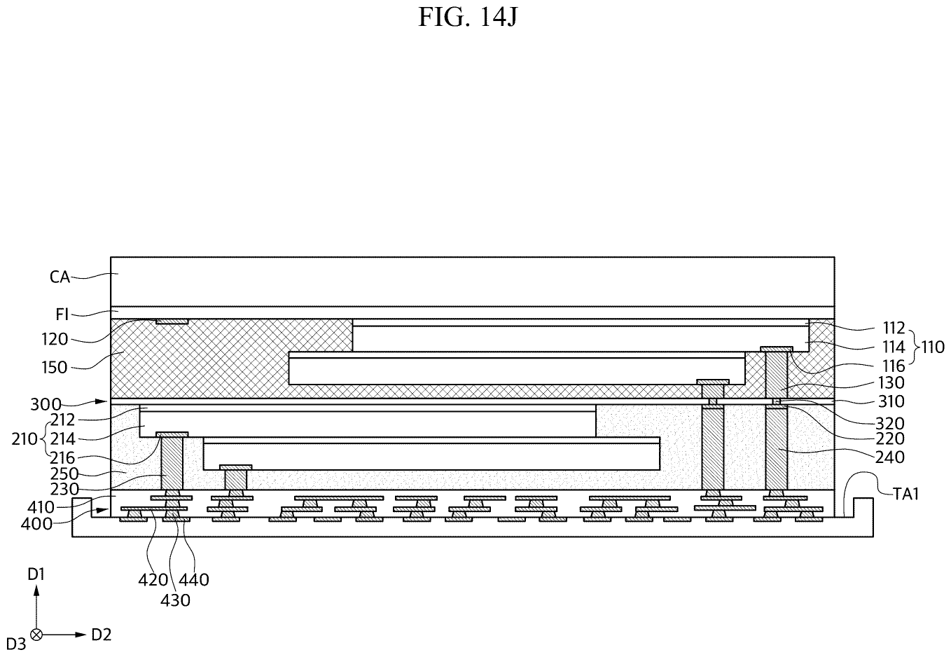

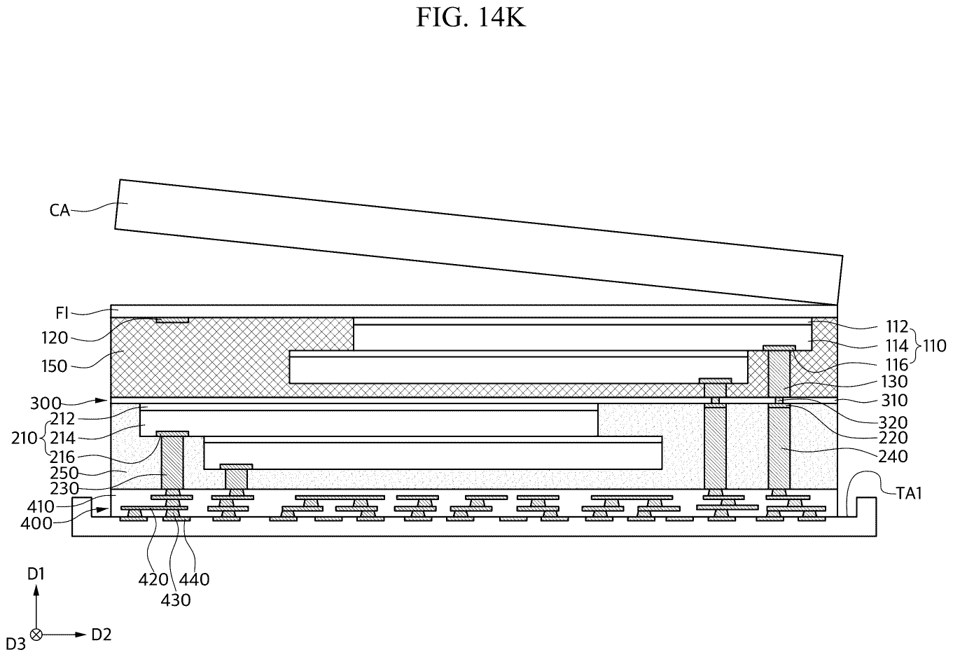

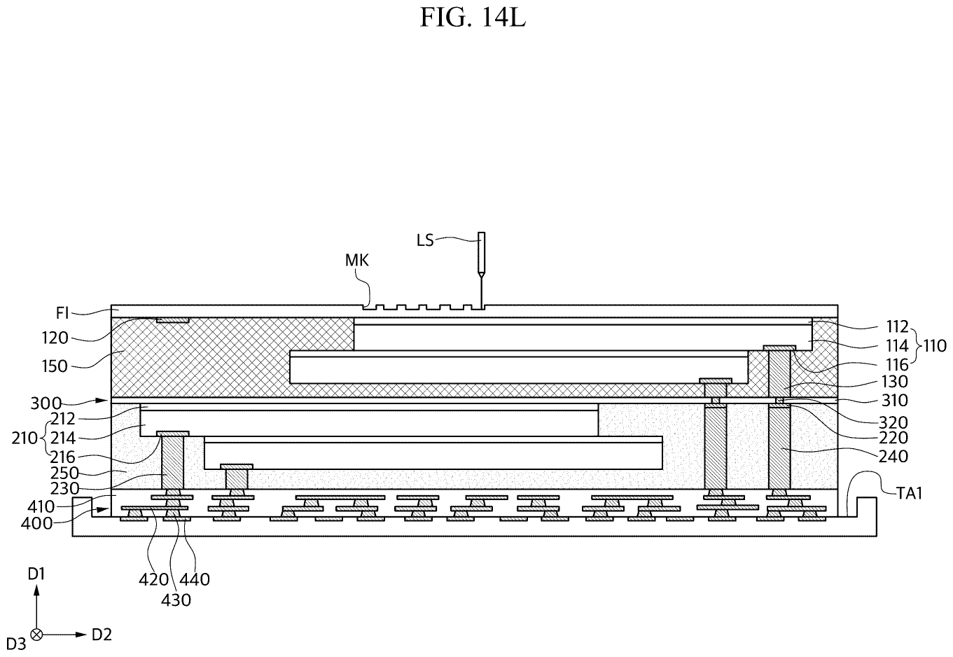

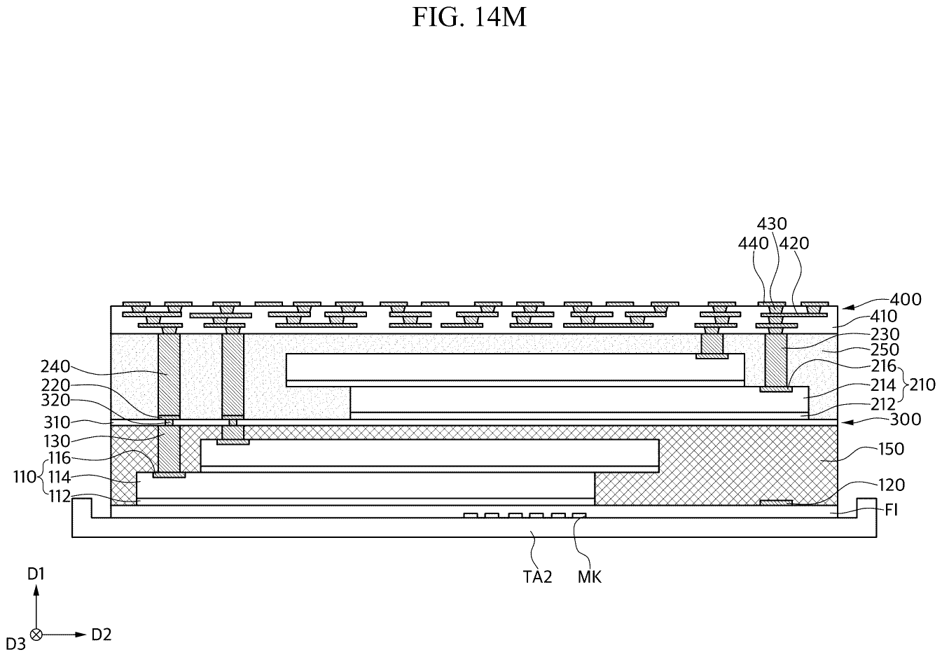

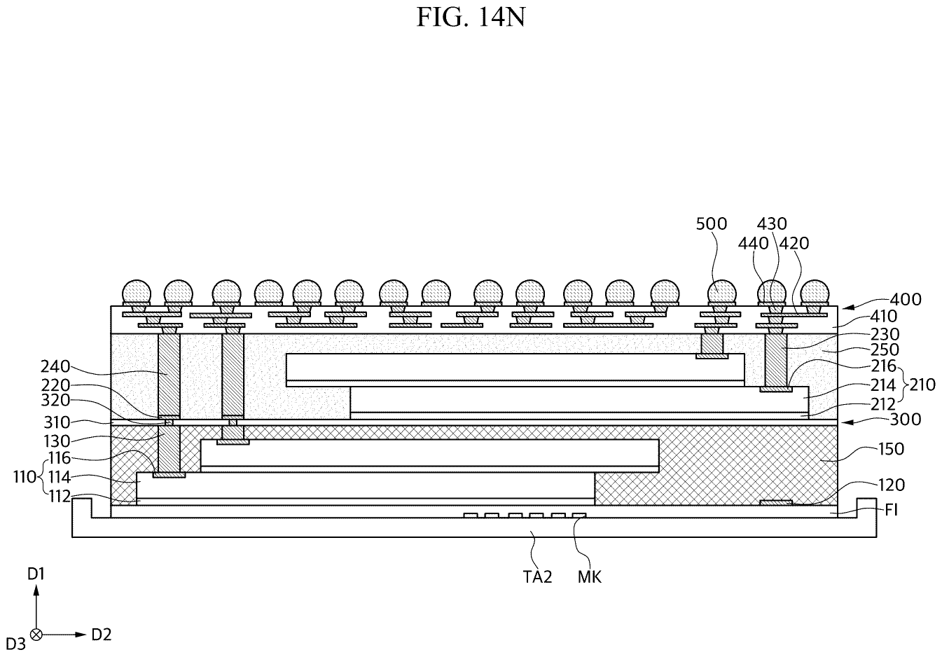

FIG. 14A to FIG. 14N are drawings illustrating a process sequence to explain a method of manufacturing a semiconductor package according to an example embodiment.

Referring to FIG. 14A, a carrier substrate CA with the film FI formed along the front side may be provided. The alignment pad 120 may be attached to the film FI. The alignment pad 120 may provide a reference point for the position where the first semiconductor die 110 is to be attached when the first semiconductor die 110 is laminated on the film FI.

According to an example embodiment, the first semiconductor die 110 may include the first adhesive layer 112, the first chip body 114 and the first connection pad 116. The first adhesive layer 112 may include a material that may be bonded to the film FI or the first chip body 114. The back side of the first adhesive layer 112 may be attached to the front side of the film FI. In an example embodiment of the present manufacturing method, a back side of an element may be defined as a side facing the film FI, and a front side of the element may be defined as a side opposite to the back side.

According to an example embodiment, the plurality of first semiconductor dies 110 may be stacked stepwise in the first direction D1. Here, the plurality of first semiconductor dies 110 are arranged offset from each other in the second direction D2, and thus the first connection pad 116 of each semiconductor die may not overlap with another semiconductor die. The first adhesive layer 112 of the first semiconductor die 110 laminated on the first semiconductor die 110 located at the bottom may be attached to the front side of the first chip body 114 located at the bottom.

According to an example embodiment, the first conductive post 130 may be attached to the first connection pad 116 of each first semiconductor die 110.

Referring to FIG. 14B, the first molding layer 150 covering the film FI may be formed on the carrier substrate CA. The first molding layer 150 may cover the film FI and surround the plurality of first semiconductor dies 110 and the plurality of first conductive posts 130.

According to an example embodiment, afterwards, the top part of the first molding layer 150 may be ground using grinding equipment AP. While the top part of the first molding layer 150 being ground, the top part of the first conductive post 130 may also be removed. The front sides of the plurality of first conductive posts 130 from which the top part has been removed may all be positioned on the same plane. Further, the front sides of the plurality of first conductive posts 130 may be positioned on the same plane as the front side of the first molding layer 150.

Referring to FIG. 14C, the intermediate redistribution structure 300 may be formed on the front side of the first molding layer 150. First, the intermediate redistribution insulation layer 310 may be formed on the front side of the first molding layer 150. Then, after the etching process on the intermediate redistribution insulation layer 310, the first intermediate redistribution via 320 may be formed by filling a trench formed through the etching process with a conductive material. After the first intermediate redistribution via 320 being formed, the first connection pad 220 may be formed on the first intermediate redistribution via 320. The first intermediate redistribution via 320 may be configured to be connected to the first conductive post 130. The first connection pad 220 may be configured to be connected to the first intermediate redistribution via 320.

Referring to FIG. 14D, FIG. 14E and FIG. 14F, a mask pattern MP may be formed on the front side of the intermediate redistribution structure 300. The mask pattern MP may include a hole H overlapping the first connection pad 220. The first connection pad 220 may be exposed through the hole H. The mask pattern MP may include at least one of a photoresist, an inorganic-based hard mask or an organic-based hard mask.

After then, the second through post 240 may be formed by filling a conductive material into the hole H of the mask pattern MP. After the second through post 240 is formed, the mask pattern MP may be removed.

Referring to FIG. 14G, the plurality of second semiconductor dies 210 may be stacked stepwise on the intermediate redistribution structure 300 in the first direction D1. The second semiconductor die 210 may include the second adhesive layer 212, the second chip body 214 and the second connection pad 216. The second adhesive layer 212 may include a material that may be bonded to the film FI or the second chip body 214.

According to an example embodiment, by the plurality of second semiconductor dies 210 being arranged offset from each other along the reverse direction-D2 of the second direction, the second connection pad 216 of each semiconductor die may not overlap another semiconductor die. The second adhesive layer 212 of the second semiconductor die 210 laminated on the second semiconductor die 210 located at the bottom may be attached to the front side of the second chip body 214 located at the bottom.

According to an example embodiment, the second conductive post 230 may be attached to the second connection pad 216 of each second semiconductor die 210.

Referring to FIG. 14H, the second molding layer 250 may be formed on the intermediate redistribution structure 300. While covering the intermediate redistribution structure 300, the second molding layer 250 may surround the plurality of second semiconductor dies 210 and the plurality of second conductive posts 230.

According to an example embodiment, afterwards, the top part of the second molding layer 250 may be ground using the grinding equipment AP. While the top part of the second molding layer 250 being ground, the top part of the second conductive post 230 may also be removed. The front sides of the plurality of second conductive posts 230 from which the top part has been removed may all be positioned on the same plane. Further, the front sides of the plurality of second conductive posts 230 may be positioned on the same plane as the front side of the second molding layer 250.

Referring to FIG. 14I, the redistribution structure 400 may be formed on the front side of the second molding layer 250. First, the redistribution insulation layer 410 may be formed on the front side of the second molding layer 250. After then, after the etching process for the redistribution insulation layer 410, the redistribution via 430 may be formed by filling a trench formed through the etching process with a conductive material. After the redistribution via 430 is formed, the redistribution pattern 420 may be formed on the redistribution via 430. The redistribution via 430 may be formed to be connected to the second conductive post 230. The process of forming the redistribution insulation layer 410, the process of forming the redistribution via 430 and the process of forming the redistribution pattern 420 may be repeated. After the iteration process, the redistribution pad 440 may be formed on the top redistribution via 430. With the formation of the redistribution pad 440, the redistribution structure 400 may be completed.

Referring to FIG. 14J and FIG. 14K, after flipping the result up to FIG. 14I, the redistribution structure 400 may be attached to a first tape TA1.

According to an example embodiment, the redistribution structure 400 may be aligned to face towards the first tape TA1. The redistribution structure 400 may be attached to the first tape TA1. In the redistribution structure 400, the exposed redistribution pad 440 from the redistribution insulation layer 410 may be attached to the first tape TA1.

According to an example embodiment, after the redistribution structure 400 is attached to the first tape TA1, the carrier substrate CA may be detached from the film FI.

Referring to FIG. 14L, the marking pattern MK may be formed on the film FI from which the carrier substrate CA has been detached using laser equipment LS. The marking pattern MK may indicate the identification information of a semiconductor package 10 (see FIG. 2).

Referring to FIG. 14M, after flipping the result up to FIG. 14L, the film FI may be attached to a second tape TA2.

According to an example embodiment, the result up to FIG. 14L may be aligned so that the film FI faces the second tape TA2. After then, the first tape TA1 may be removed from the redistribution structure 400. With the first tape TA1 removed, the redistribution pad 440 of the redistribution structure 400 may be exposed to the outside.

Referring to FIG. 14N, the external terminal 500 may be attached to the redistribution pad 440. After the external terminal 500 is attached, the semiconductor package according to an example embodiment may be completed by the second tape TA2 being removed from the film FI.

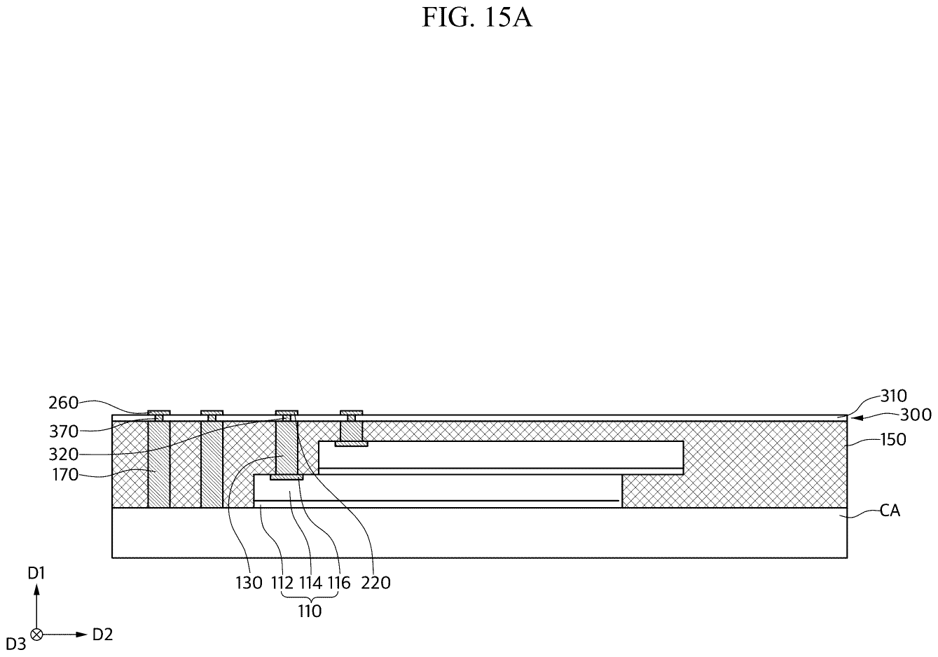

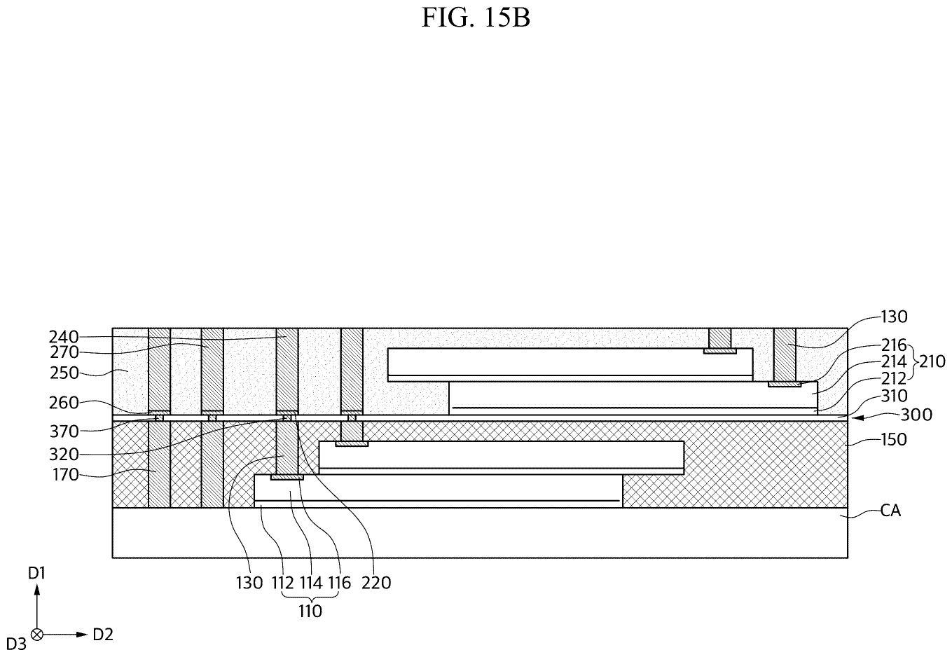

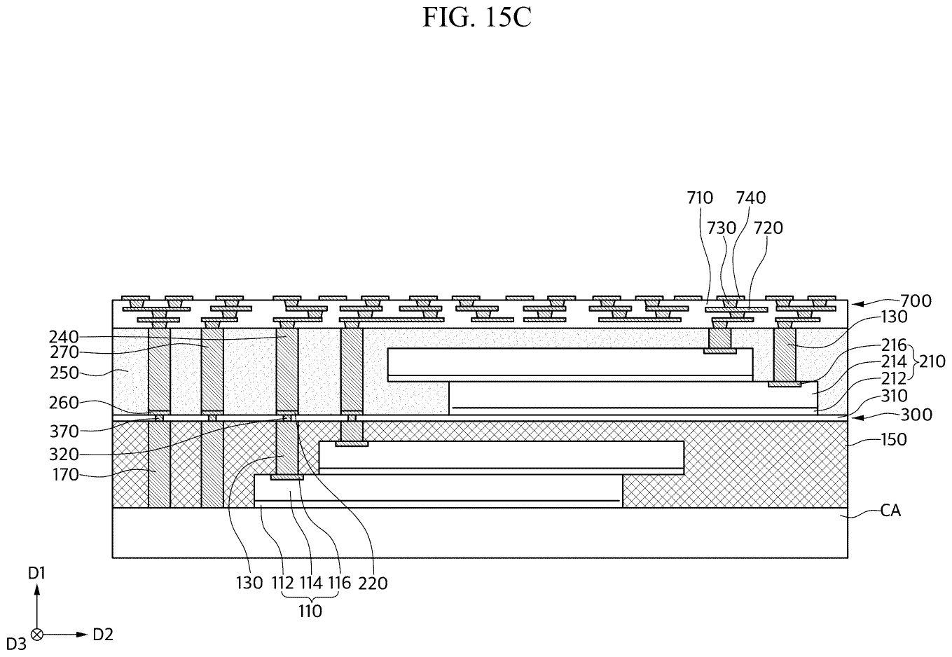

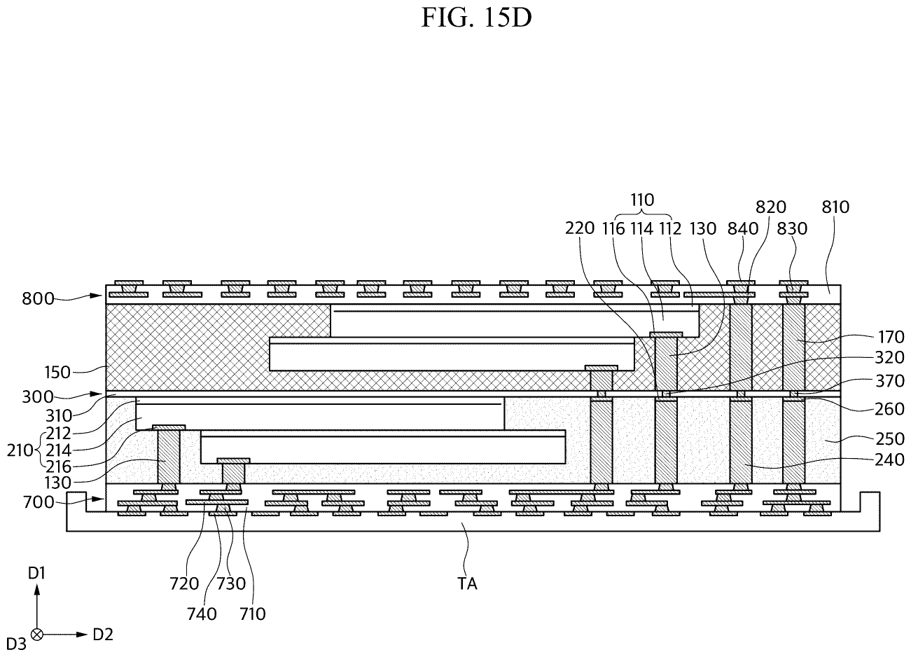

FIG. 15A to FIG. 15D are drawings illustrating a portion of a process in sequence to explain a method of manufacturing a semiconductor package according to another example embodiment.

FIG. 15A is a drawing illustrating part of a process for manufacturing a semiconductor package according to another example embodiment. FIG. 15A may correspond to part of the semiconductor package manufacturing process illustrated in FIG. 14C. Except further forming the first through post 170, the process for manufacturing the result illustrated in FIG. 15A may be substantially the same as the series of processes illustrated in FIG. 14A to FIG. 14C. Therefore, the contents already described with reference to FIG. 14A to FIG. 14C will be omitted below.

According to an example embodiment, unlike the results of FIG. 14C, the first through post 170 may be formed on the carrier substrate CA. After the first through post 170 is formed, which extended to the first direction D1, the first molding layer 150 may be formed that surrounds the first through post 170. After then, as illustrated in FIG. 14C, the intermediate redistribution structure 300 may be formed. The first connection pad 220 and the second connection pad 260 may be formed on the intermediate redistribution structure 300, which are connected to the first intermediate redistribution via 320 and the second intermediate redistribution via 370.

Referring to FIG. 15B, the plurality of second semiconductor dies 210 may be laminated on the intermediate redistribution structure 300. After then, the second through post 240, the third through post 270 and the second conductive post 230 may be formed. The second through post 240 and the second conductive post 230 may be formed through a series of processes illustrated in FIG. 14D to FIG. 14H. Therefore, the contents already described with reference to FIG. 14D to FIG. 14H will be omitted below.

According to an example embodiment, the third through post 270 may be formed by the same process as the process of the second through post 240. The third through post 270 may be configured to connect to the second connection pad 260.

After then, formed may be the plurality of second semiconductor dies 210, the second through post 240, the third through post 270 and the second molding layer 250 sealing the second conductive post 230. The thermal expansion coefficient of the second molding layer 250 may be lower than the thermal expansion coefficient of the first molding layer 150.

Referring to FIG. 15C, the first redistribution structure 700 may be formed on the second molding layer 250. The first redistribution via 730 of the first redistribution structure 700 may be formed to connect with the second through post 240, the third through post 270 and the second conductive post 230. According to an example embodiment, a conductive pad may be interposed between the first redistribution via 730 and the second through post 240, and a conductive pad may be interposed between the third through post 270 and the second conductive post 230. The thickness of the first redistribution structure 700 may be thicker than the thickness of the intermediate redistribution structure 300.

Referring to FIG. 15D, after flipping the result of FIG. 15C, the first redistribution structure 700 may be attached to a tape TA. After the first redistribution structure 700 is attached to the tape TA, the second redistribution structure 800 may be formed on the back side of the first molding layer 150. The second redistribution via 830 of the second redistribution structure 800 may be formed to connect to the first through post 170. According to an example embodiment, a conductive pad may be interposed between the second redistribution via 830 and the first through post 170. While the thickness of the second redistribution structure 800 being thicker than the thickness of the intermediate redistribution structure 300, the thickness of the second redistribution structure 800 may be thinner than the thickness of the first redistribution structure 700.

A part of the process of manufacturing the semiconductor package illustrated in FIG. 15D may correspond to FIG. 14I. After then, as illustrated in FIG. 14N, after flipping the result up to FIG. 15D, the external terminal 500 may be attached to the first redistribution pad 740 of the first redistribution structure 700. After the external terminal 500 is attached, the tape TA may be removed from the first redistribution structure 700. After the tape TA is removed, when the semiconductor device 600 is mounted on the first redistribution structure 700, the semiconductor package 50 according to an example embodiment illustrated in FIG. 12 may be completed.

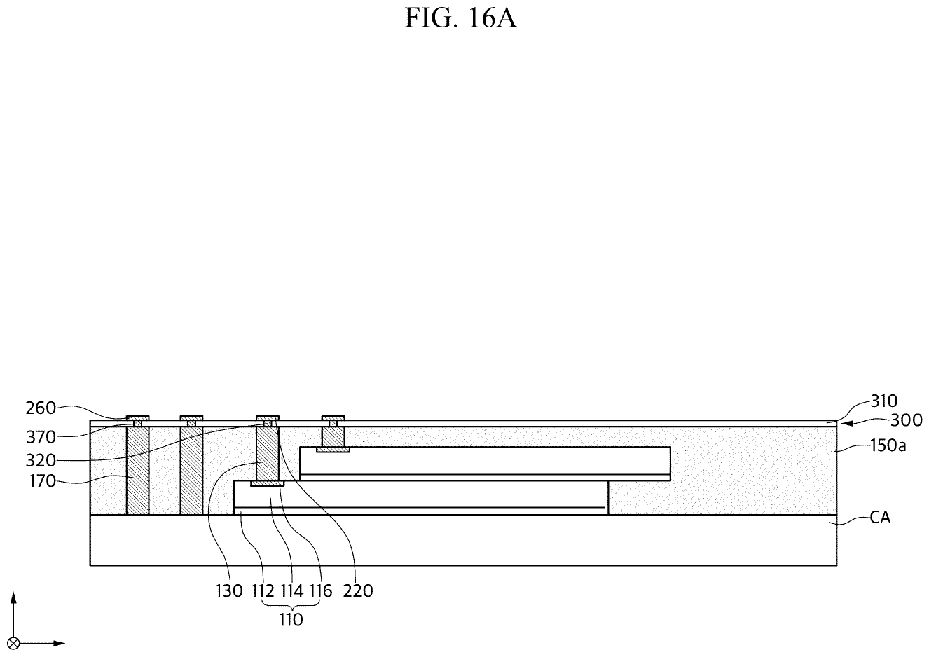

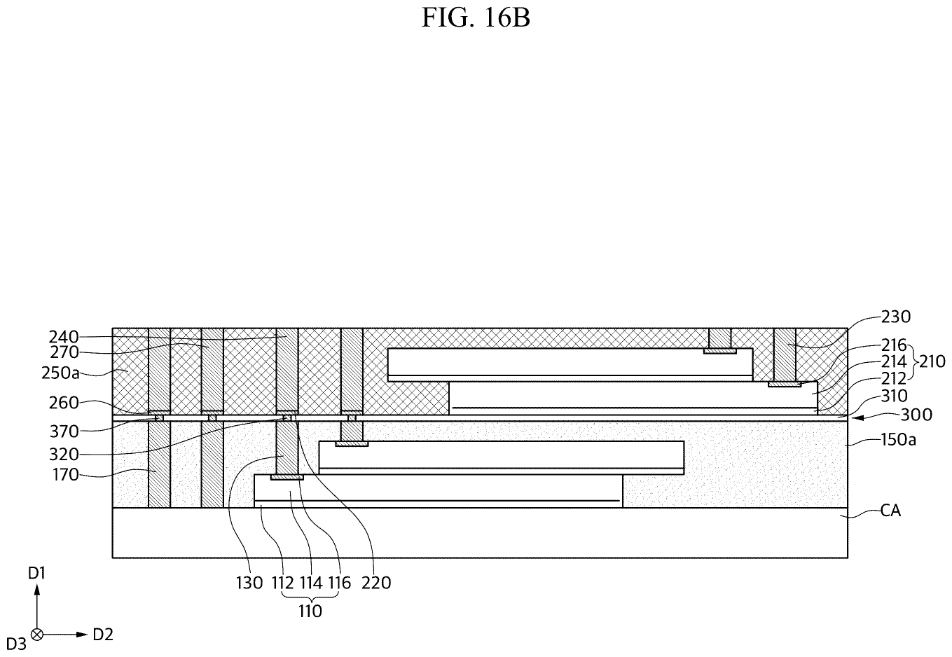

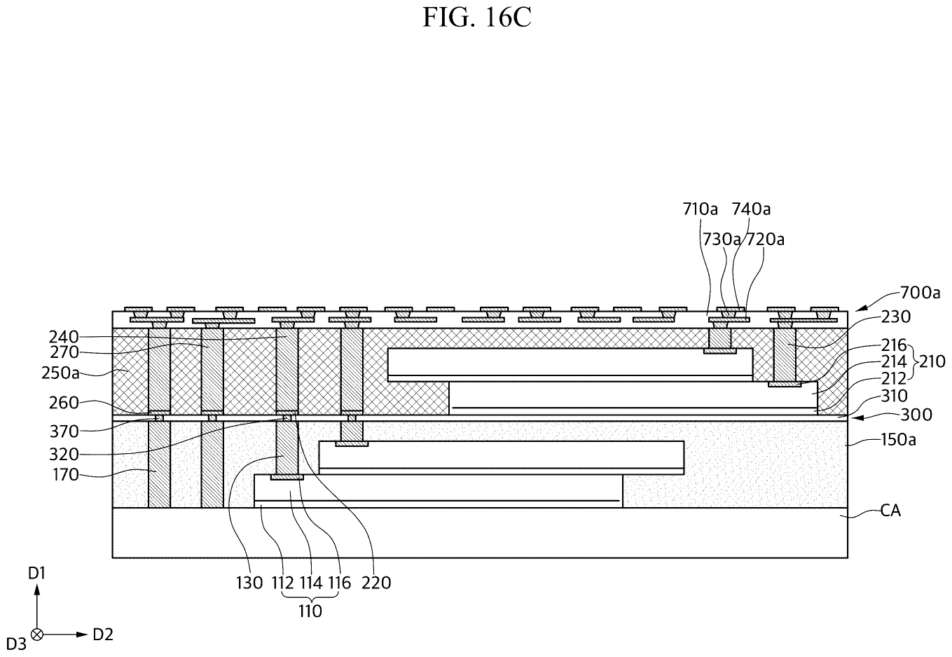

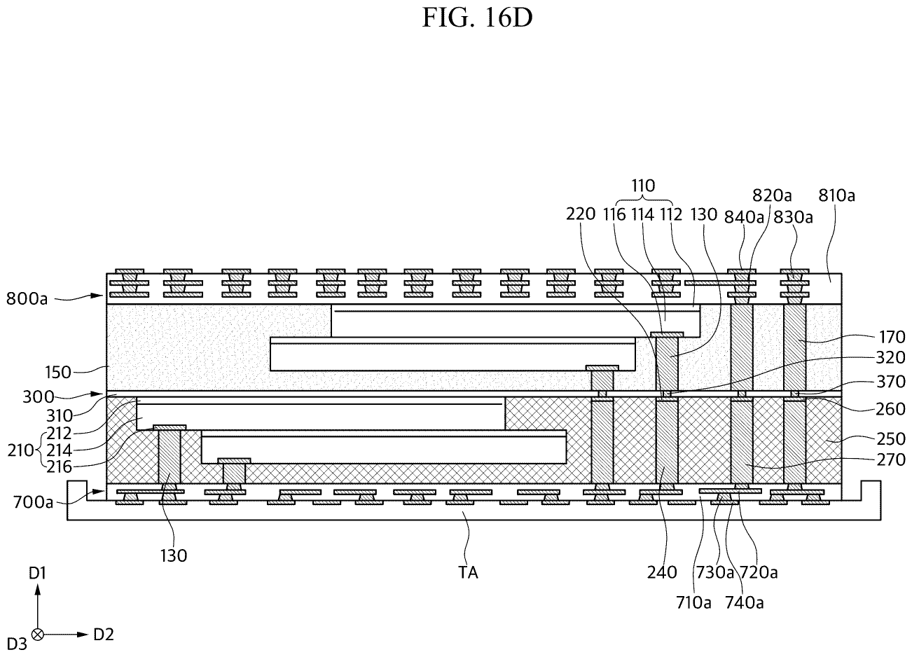

FIG. 16A to FIG. 16D are drawings illustrating a portion of a process in sequence to explain a method of manufacturing a semiconductor package according to another example embodiment.

FIG. 16A is a drawing illustrating part of a process for manufacturing a semiconductor package according to another example embodiment. FIG. 16A may correspond to the part of the semiconductor package manufacturing process illustrated in FIG. 15A. Except that the thermal expansion coefficient of the first molding layer 150a illustrated in FIG. 16A is different from the thermal expansion coefficient of the first molding layer 150a illustrated in FIG. 15A, the process for manufacturing the result illustrated in FIG. 16A may be substantially the same as the series of processes illustrated in FIG. 14A to FIG. 14C. Therefore, the contents already described with reference to FIG. 14A to FIG. 14C and FIG. 16A will be omitted below.

According to an example embodiment, the first molding layer 150a may surround the first through post 170, the first conductive post 130 and the plurality of first semiconductor dies 110. When compared to the result in FIG. 15A, the thermal expansion coefficient of the first molding layer 150a illustrated in FIG. 16A may be lower than the thermal expansion coefficient of the first molding layer 150 illustrated in FIG. 15A.

Referring to FIG. 16B, the plurality of second semiconductor dies 210 may be laminated on the intermediate redistribution structure 300. After then, the second through post 240, the third through post 270 and the second conductive post 230 may be formed. The second through post 240 and the second conductive post 230 may be formed through a series of processes illustrated in FIG. 14D to FIG. 14H. Therefore, the contents already described with reference to FIG. 14D to FIG. 14H will be omitted below.

According to an example embodiment, the third through post 270 may be formed by the same process as the second through post 240. The third through post 270 may be configured to be connected to the second connection pad 260.

After then, the second molding layer 250a sealing the plurality of second semiconductor dies 210, the second through post 240, the third through post 270 and the second conductive post 230 may be formed. Unlike the second molding layer 250 illustrated in FIG. 15B, the thermal expansion coefficient of the second molding layer 250a may be higher than the thermal expansion coefficient of the first molding layer 150a.

Referring to FIG. 16C, the first redistribution structure 700a may be formed on the second molding layer 250a. The first redistribution via 730a of the first redistribution structure 700a may be formed to be connected with the second through post 240, the third through post 270 and the second conductive post 230. According to an example embodiment, a conductive pad may be interposed between the first redistribution via 730a and the second through post 240, and a conductive pad may be interposed between the third through post 270 and the second conductive post 230. The thickness of the first redistribution structure 700a may be thicker than the thickness of the intermediate redistribution structure 300.

Referring to FIG. 16D, after flipping the result of the FIG. 16C, the first redistribution structure 700a may be attached to the tape TA. After the first redistribution structure 700a is attached, the second redistribution structure 800a may be formed on the back side of the first molding layer 150a. The second redistribution via 830a of the second redistribution structure 800a may be formed to be connected to the first through post 170. According to an example embodiment, a conductive pad may be interposed between the second redistribution via 830a and the first through post 170. The thickness of the second redistribution structure 800a may be thicker than the thickness of the first redistribution structure 700a and the thickness of the intermediate redistribution structure 300.

A part of the process of manufacturing the semiconductor package illustrated in FIG. 16D may correspond to FIG. 14I. After then, as illustrated in FIG. 14N, after flipping the result up to FIG. 16D, the external terminal 500 may be attached to the first redistribution pad 740 of the first redistribution structure 700a. After the external terminal 500 is attached, the tape TA may be removed from the first redistribution structure 700a. After the tape TA is removed, when the semiconductor device 600 is mounted on the first redistribution structure 700a, the semiconductor package 60 according to an example embodiment illustrated in FIG. 13 may be completed.

A semiconductor package according to an example embodiment may include a plurality of vertically stacked package structures. Each of the plurality of package structures may include a redistribution structure enabling electrical connection. The redistribution structure serves to transmit electrical signals within the package structure, and the thermal expansion coefficient of the molding layer in contact with this may be adjusted according to the thickness of the redistribution structure.

Typically, the greater the thickness of the redistribution structure, the greater the extent of expansion due to thermal energy. Accordingly, in an example embodiment, the thermal expansion coefficient of the molding layer in contact with the redistribution structure is formed to be relatively low in order for the thermal strain to be suppressed. By uniformly adjusting the thermal expansion rate between multiple vertically stacked package structures, warpage across the entire package may be minimized and reliability improved. Through this, the operational stability of the semiconductor package may be secured, and the optimized performance may be implemented.

The effects achievable by the present disclosure are not limited to the effect mentioned above, and other effects not mentioned will be clearly understood by those of ordinary skill in the art to which the present disclosure pertains from the following description.

As described above, example embodiments are disclosed with respect to the drawings in the present disclosure. In the present disclosure, the example embodiments are described using specific terms, but the terms are used solely for the purpose of explaining the technical ideas of the present disclosure and are not intended to limit the meaning or scope of the present disclosure as set forth in the claims. Therefore, those skilled in the art will understand that various modifications and equivalent example embodiments are possible from this.

What is claimed is:

1. A semiconductor package comprising:
an intermediate redistribution structure with a first thickness;
a first package structure comprising a first molding layer that is in contact with a back side of the intermediate redistribution structure;
a second package structure comprising a second molding layer that is in contact with a front side that is opposite to the back side of the intermediate redistribution structure; and
a first redistribution structure that is in contact with a front side of the second molding layer and with a second thickness that is thicker than the first thickness,
wherein a thermal expansion coefficient of the second molding layer is less than a thermal expansion coefficient of the first molding layer.

2. The semiconductor package of claim 1, wherein the intermediate redistribution structure comprises an intermediate redistribution insulation layer that is in contact with the first molding layer,
wherein the intermediate redistribution insulation layer has a thermal expansion coefficient that is greater than the thermal expansion coefficient of the first molding layer.

3. The semiconductor package of claim 1, wherein the first redistribution structure comprises a first redistribution insulation layer that is in contact with the second molding layer,
wherein the first redistribution insulation layer has a thermal expansion coefficient that is greater than a thermal expansion coefficient of the second molding layer.

4. The semiconductor package of claim 1, wherein the first molding layer comprises a first molding material and a plurality of first fillers that are buried in the first molding material,
wherein the second molding layer comprises a second molding material and a plurality of second fillers that are buried in the second molding material, and
wherein a thermal expansion coefficient of the plurality of first fillers is less than a thermal expansion coefficient of the first molding material, and a thermal expansion coefficient of the plurality of second fillers is less than a thermal expansion coefficient of the second molding material.

5. The semiconductor package of claim 4, wherein a content of the plurality of first fillers is less than a content of the plurality of second fillers.

6. The semiconductor package of claim 4, wherein the thermal expansion coefficient of the second molding material is less than the thermal expansion coefficient of the first molding material.

7. The semiconductor package of claim 1, wherein a side of the first molding layer, a side of the second molding layer, a side of the first package structure and a side of the second package structure are aligned with respect to each other.

8. The semiconductor package of claim 1, wherein the thermal expansion coefficient of the first molding layer is 20 part per million (ppm)/K or greater, and
wherein the thermal expansion coefficient of the second molding layer is 10 ppm/K or less.

9. A semiconductor package comprising:
an intermediate redistribution structure with a first thickness;
a first semiconductor die stack comprising a plurality of first semiconductor dies that are stacked in a first step structure in a first direction intersecting a back side of the intermediate redistribution structure in the intermediate redistribution structure;
a second semiconductor die stack comprising a plurality of second semiconductor dies that are stacked in a second step structure in the first direction under the intermediate redistribution structure;
a first redistribution structure that is disposed on the second semiconductor die stack and with a second thickness that is thicker than the first thickness;
a first molding layer covering the first semiconductor die stack and comprising a plurality of first fillers with a first average diameter; and
a second molding layer covering the second semiconductor die stack and comprising a plurality of second fillers with a second average diameter that is greater than the first average diameter.

10. The semiconductor package of claim 9, wherein the first semiconductor die stack and the intermediate redistribution structure are spaced apart from each other in the first direction with the first molding layer interposed therebetween, and
wherein the second semiconductor die stack and the first redistribution structure are spaced apart from each other in the first direction with the second molding layer interposed therebetween.

11. The semiconductor package of claim 9, further comprising a film comprising a marking pattern that is disposed on the first semiconductor die stack to configured to indicate identification information.

12. The semiconductor package of claim 9, wherein a thermal expansion coefficient of the plurality of first fillers is greater than a thermal expansion coefficient of the plurality of second fillers.

13. The semiconductor package of claim 9, further comprising a conductive post connecting each of the plurality of first semiconductor dies and the intermediate redistribution structure,
wherein the conductive post is covered by the first molding layer.

14. The semiconductor package of claim 13, further comprising a through post configured to electrically connect the intermediate redistribution structure and the first redistribution structure by penetrating the second molding layer,
wherein the through post overlaps the conductive post in the first direction.

15. The semiconductor package of claim 9, wherein the plurality of first semiconductor dies is offset from each other in a second direction intersecting the first direction, and
wherein the plurality of second semiconductor dies is offset from each other in a direction that is opposite to the second direction.

16. The semiconductor package of claim 9, wherein the plurality of first semiconductor dies is offset from each other in the second direction intersecting the first direction, and
wherein the plurality of second semiconductor dies is offset from each other in the second direction.

17. The semiconductor package of claim 9, further comprising a second redistribution structure that is disposed on the first semiconductor die stack and with a third thickness that is thicker than the first thickness and thinner than the second thickness,
wherein the second redistribution structure is in contact with the first molding layer.

18. The semiconductor package of claim 17, wherein the first redistribution structure comprises a first number of first stacked redistribution insulation layers that are stacked in the first direction, and
wherein the second redistribution structure comprises a second number of second stacked redistribution insulation layers that are stacked in the first direction and wherein the second number is smaller than the first number.

19. A semiconductor package comprising:
an intermediate redistribution structure comprising a first number of intermediate redistribution insulation layers;
a first semiconductor die stack comprising a plurality of first semiconductor dies that are stacked in a step structure in a first direction intersecting a back side of the intermediate redistribution structure in the intermediate redistribution structure;
a second semiconductor die stack comprising a plurality of second semiconductor dies that are stacked in a reversal step structure in the first direction under the first semiconductor die stack;
a first redistribution structure comprising a second number of first redistribution insulation layers that are stacked in the first direction, that are disposed under the second semiconductor die stack and wherein the second number is greater than the first number;
a first molding layer covering the first semiconductor die stack and comprising a plurality of first fillers with a first average diameter and a first molding material configured to bury the plurality of first fillers; and
a second molding layer covering the second semiconductor die stack and comprising a plurality of second fillers with a second average diameter and a second molding material configured to bury the plurality of second fillers,
wherein the first average diameter is less than the second average diameter, and
wherein a thermal expansion coefficient of the first molding material is greater than a thermal expansion coefficient of the second molding material.

20. The semiconductor package of claim 19, wherein a filler of which diameter is greatest among the plurality of first fillers has a diameter which is 10 μm or greater, and
wherein a filler of which diameter is greatest among the plurality of second fillers has a diameter which is 10 μm or less.
